(19) United States
(12) Patent Application Publication
(10) Pub. No.: US 2012/0002455 A1
(43) Pub. Date: Jan. 5, 2012

(54) MINITURIZATION TECHNIQUES, SYSTEMS, AND APPARATUS RELATNG TO POWER SUPPLIES, MEMORY, INTERCONNECTIONS, AND LEDS

(76) Inventors: Jason A. Sullivan, (US); Charles Abdouch, (US)

(21) Appl. No.: 13/153,224

(22) Filed: Jun. 3, 2011

Related U.S. Application Data
(60) Provisional application No. 61/352,359, filed on Jun. 7, 2010.
(60) Provisional application No. 61/352,349, filed on Jun. 7, 2010.
(60) Provisional application No. 61/352,369, filed on Jun. 7, 2010.
(60) Provisional application No. 61/352,378, filed on Jun. 7, 2010.

(51) Int. Cl. G11C 5/02; H05B 37/02; H05K 7/00; H01R 31/06

(52) U.S. Cl. 365/51; 439/628; 315/294; 361/760

(57) ABSTRACT

Miniaturization techniques, systems, and apparatus relating to power supplies, memory, interconnections, and LEDS are described herein. Specifically, some aspects of the invention relate to techniques for miniaturization of power supplies. Other aspects relate to systems and methods for optimizing memory performance in a computer device or system. Still further, some aspects relate to systems and methods for miniaturizing and optimizing memory layout on a circuit board. Other aspects relate to systems and methods for attaching an integrated circuit, which comprises an array of pins, to a circuit board through the use of an adaptor that comprises a BGA, and which is configured to electrically and physically attach to the circuit board. Furthermore, some aspects relate to systems and methods for achieving activation of at least one multi-color LED, such as a bi-color or tri-color LED, using multiple electrical ground outputs or signals intended to activate only a single unicolor LED.

### CROSS-REFERENCE TO RELATED APPLICATIONS

This application claims the benefit of the following provisional applications: U.S. Provisional Application No. 61/352,359, filed Jun. 7, 2010, entitled “MINITURIZED POWER SUPPLY;” U.S. Provisional Application No. 61/352,349, filed Jun. 7, 2010, entitled “SYSTEMS AND METHODS FOR OPTIMIZING MEMORY PERFORMANCE;” U.S. Provisional Application No. 61/352,369, filed Jun. 7, 2010, entitled “SYSTEMS AND METHODS FOR PROVIDING A PIN GRID ARRAY TO BALL GRID ARRAY ADAPTOR;” and U.S. Provisional Application No. 61/352,378, filed Jun. 7, 2010, entitled “SYSTEMS AND METHODS FOR ACTIVATING MULTI-COLOR LIGHT EMITTING DIODES; the entire disclosures of all of the applications are hereby incorporated by reference.

### BACKGROUND OF THE INVENTION

1. Field of the Invention

The present invention relates to electronic systems and components. In particular, the present invention relates to miniaturization techniques, systems, and apparatus relating to power supplies, memory, interconnections, and LEDs.

2. Background and Related Art

Electronic systems, such as computers, are becoming increasingly ubiquitous. For instance, electronic systems, including computers, are constantly being utilized in an ever growing number of divergent fields of technologies and to perform an ever increasing variety of functions. As the use and function of electronic systems increases, there is often a need to improve some of the systems' components. In particular, as computers and other electronic systems become more complicated, advanced, and compact, there is a need to miniaturize and otherwise improve several of the system components. In this regard, power supplies, memory, integrated circuit connectors, and light emitting diode (“LED”) circuitry are some examples of computer components that can be miniaturized or otherwise improved.

With respect to power supplies, electronic systems often include a power supply which converts raw input power (e.g., alternating current supplied from commercial mains) into necessary internal supply voltages (e.g., direct current voltages such as 5 volts, 3.3. volts, etc.) within the systems. Many electronic systems also include components (e.g., integrated circuits) that require multiple voltages and require special sequencing of the voltages during ramp up and ramp down.

While power supplies are usually a necessary part of an electronic system, they can provide many undesirable aspects. For example, noise generated by a power supply can be conducted or radiated to susceptible components of the electronic systems—causing improper operation of the susceptible components. Accordingly, a difficult aspect of power supply design is to ensure that undesired noise is not emitted from the power supply. On the other hand, modern power supplies often include complex monitoring circuitry that can be susceptible to noise. Noise ingress into the monitoring circuitry can result in improper operation, such as erroneous shut down, poor regulation, and other undesirable effects. Power supplies also tend to be bulky, and can use up valuable, limited space on printed circuit boards.

Due to the difficulty in meeting the myriad design requirements, many system designers are reluctant to change established power supply design approaches. For example, some component suppliers provide a reference power supply design that purports to meet the requirements of their components. Even though the reference power supply design may not be optimized for cost or circuit board area, designers often simply adopt the component supplier's reference design. While the supplier's reference design may provide a suboptimal solution from a cost, area, or performance perspective, using such a design can help to reduce risk to the overall project.

As electronic systems become increasingly smaller, however, the cost and space consumed by power supplies has become a greater percentage of the overall electronic system. This is particularly pronounced in very small computer systems, which target a variety of different markets. For example, for a computer system which is designed to fit in a volume on the order of about 65 cubic centimeters (about 25 cubic inches), a power supply design which requires in excess of 10 square centimeters (about 4 square inches) of board area may not be practical. Accordingly, it has been recognized by the present inventors that miniaturization of power supply systems would be beneficial.

Regarding memory, most (if not all) of today's computer systems include memory, which is typically held on a memory module. A memory module typically includes a circuit board, such as a printed circuit board (“PCB”), with a number of integrated circuits (“ICs”), or chips, coupled to one or more surfaces of the circuit board. The chips are memory devices to provide memory resources to a computing platform such, as a personal computer (“PC”). One type of memory module uses dynamic random access memory (“DRAM”) chips in a dual data rate (“DDR”) manner. These modules arrange the DRAM chips as a single in-line memory module (“SIMM”) or as a dual in-line memory module (“DIMM” or “DIMMS”).

The circuit board (or PCB) can have a connector along one edge that is compatible with a socket connector on a motherboard for integration of the memory module into the computing platform. One type of technology (known as a DDR2 DIMM) has an electrical connector with 240 pins.

DIMMS include multiple DRAM chips coupled to the PCB. For example, some implementations include eight DRAM chips coupled to the PCB. These DRAM chips include a set of terminating resistors that prevent data corruption and line loss in the transmission lines. The combination of the DIMMS and the terminating resistors has a large footprint on the PCB, which limits the miniaturization of the system.

Cross talk and line loss further limit memory layout configurations by requiring memory modules to be located away from the memory controller (which is occasionally integrated into the processor) in order to allow lines between the memory controller and the memory modules to fan out or otherwise have sufficient space between adjacent lines. Generally, the physical size of the DRAMs (typically greater than 12.5 mm), combined with the DIMM sockets, decoupling capacitors, and termination resistors, require that the memory modules and the memory controller are located more than 6.4 centimeters (2.5 inches) away from each other.

Turning now to integrated circuit connectors, central processing units (“CPU”) can be electrically and physically connected to a circuit board in a variety of manners. Indeed, in some cases, a CPU is soldered directly to a circuit board. In other cases, however, a CPU is attached to a circuit board through the use of a CPU socket.

Where a CPU is attached to the circuit board through the use of a CPU socket, the CPU socket can function in a variety of manners. Indeed, in some instances, the CPU socket comprises a plastic housing that has a latch and a metal contact for each of the pins on the CPU. In such instances, when a CPU with a pin grid array (“PGA”) is inserted in the CPU socket and the latch is closed, the metal contacts are forced into contact with the pins of the CPU's PGA. In other instances in which the CPU comprises a land grid array (“LGA”) and the CPU socket comprises a corresponding PGA, the CPU is placed in the CPU socket and the latch is closed over the CPU to secure it in place and to force the LGA into contact with corresponding PGA within the CPU socket.

While conventional methods for attaching CPUs to circuit boards have been found to be useful, such methods are not necessarily without their shortcomings. For instance, where a CPU is directly attached to a circuit board, the CPU (which is often the most expensive component of the circuit board) can be very difficult to remove from the circuit board. Accordingly, when such a CPU fails or when a user desires to upgrade such a CPU, it can be more convenient to replace the entire circuit board than to remove the CPU and replace it with another.

In another example, where a CPU attaches to a first side of a circuit board through the use of a PGA that extends from the CPU or a CPU socket and penetrates the circuit board, the CPU can prevent components from being placed an opposite side of the board—directly behind the CPU. In other words, a CPU that attaches to a circuit board through the use of a PGA that penetrates the board, can require more real estate than would be required if the CPU were strictly attached to one side of the board.

In still another example, in some cases in which a CPU attaches to a circuit board through the use of a conventional CPU socket, the CPU socket, with its lever, tends to have a larger footprint than does the CPU. Accordingly, in this example, the CPU socket can take up excessive real estate on a circuit board, which can be detrimental in applications in which space is a limiting factor.

In yet another example, in some cases in which a CPU is attached to a circuit board through the use of a CPU socket, the metal contacts in the CPU socket can be damaged during their production process, during insertion of the CPU's PGA, or as the circuit board is exposed to shock and vibration during use. As a result of this damage, the CPU socket can lose its electrical connection with one or more of the CPU's pins and, thereby, causes the CPU to fail or to function improperly.

Turning now to LEDs, LEDs are an increasingly ubiquitous semiconductor light source capable of emitting high intensity light across the visible wavelength (or color) spectrum, as well as ultraviolet and infrared wavelengths. LEDs can present many advantages over traditional light sources, including lower energy consumption, longer lifetime, improved robustness, smaller size, faster switching, and greater durability and reliability. As a result, LEDs are frequently used as indicator lamps in electronic devices and are increasingly used in numerous diverse applications, including replacing traditional light sources in aviation lighting, automotive lighting, traffic signal illumination, text and/or video display illumination, sensor illumination, sign or other visual and/or informational display device illumination, ambient or direct lighting, and operable printhead lighting.

In electronics, a diode is one of the simplest sorts of semiconductor devices, comprising a two-terminal electronic component that conducts electric current in only one direction (called the diode's “forward” direction). Generally speaking, a semiconductor is a material with a varying ability to conduct electrical current. Most LEDs consist of a chip of semiconducting material “doped” with impurities to create a p-n junction with electrodes or leads on each end. A p-n junction generally consists of a single semiconductor having a region on one side that contains negative charge carriers (electrons), resulting in an n-type region, while a region on the other side contains positive charge carriers (holes), resulting in a p-type region. The term “junction” refers to the boundary interface where the two regions of the semiconductor meet. In operation, current flows in a direction from the p-type side (the anode) to the n-type side (the cathode). The wavelength of light emitted, and therefore its color, depends on the band gap energy of the material forming the p-n junction.

The basic LED circuit is an electric power circuit used to power a LED. It consists of a voltage source powering two components connected in series: a current limiting resistor and an LED. The LED circuit is powered and produces light when a positive voltage and a negative voltage source are connected to the appropriate LED electrodes or leads, respectively.

Ethernet is a widely-installed local area network (“LAN”) technology defining a number of wiring and signaling standards for the physical layer of the open systems interconnect (“OSI”) networking model as well as a common addressing format and media access control at the data link layer. Using an Ethernet interface, many computer devices can communicate with one another over a LAN. Ethernet is standardized as IEEE 802.3.

As mentioned above, LEDs are commonly used as indicator lamps in electronic devices. For example, Ethernet ports are commonly equipped with two indicator LEDs. One LED often indicates activity (“ACT signal”) on the Ethernet port while the other LED indicates the speed (Speed signal) of the Ethernet link (e.g., 10 Mb, 100 Mb, or 1000 Mb and so forth). Generally, the indicator LED denoting activity will blink when the port is active (i.e., transmitting or receiving). The LED indicating speed, on the other hand, will often be either lit or turned off depending on the speed of the Ethernet link (e.g., off for 10 Mb or lit for 100 Mb and so forth).

Generally, an Ethernet port is connected to and driven by an Ethernet chip located on a PCB. The chip can also operate the Ethernet's indicator LEDs. Some Ethernet chips, such as some of the chips manufactured by Broadcom Corp., have internal circuitry incorporated into the chip during the manufacturing process which automatically generates a speed signal based on the speed of the Ethernet link and activates the appropriate Ethernet port indicator LED accordingly. Often bi-color LEDs are used in connection with such chips. Bi-color LEDs are actually two different LEDs housed in one case or lens. They consist of two semiconductor dies connected to the same two leads anti-parallel to each other. Current flow in one direction produces one color, and current flow in the opposite direction produces the other color. The combination of chips having such internal circuitry and bi-color LEDs permit the automated visual indication of a range of three discrete speeds. For example, at 10 Mb the bi-color LED is off, at 100 Mb the bi-color LED is one color, such as green, and at 1000 Mb the bi-color LED is the alternate color, such as amber.

Thus, while techniques currently exist relating to the use of power supplies, memory, IC connectors, and LED circuitry, challenges still exist. Accordingly, it would be an improvement in the art to augment or even replace current techniques with other techniques.

### SUMMARY OF THE INVENTION

The present invention relates to electronic systems and components. In particular, the present invention relates to miniaturization techniques, systems, and apparatus relating to power supplies, memory, interconnections, and LEDs.

Some aspects of the invention relate to power supplies. In particular, in some implementations, the invention relates to a miniaturized power supply that includes a PCB (or other circuit board). In such implementations, a first active component is disposed on a first side of the PCB. A second active component is disposed on a second side of the PCB and electrically connected to the first active component. The first side and the second side are different from each other.

In some implementations, a method of making a miniaturized power supply is provided. The method includes obtaining a design schematic for the power supply, wherein the design schematic comprises a plurality of electronic components. Some of the electronic components can be active components. Additional operations in the method are selecting positions on a first side of a PCB for first ones of the active components and selecting positions on a second side of the PCB for second ones of the active components. The first side and the second side are different from each other. The positions of the second ones of the plurality of active components are selected with respect to the positions of the first ones of the plurality of active components. The method can also include defining interconnections between the plurality of electronic components, wherein the interconnections comprise traces and vias to form a PCB layout.

Some aspects of the invention relate to memory. In particular, some aspects of the present invention relate to systems and methods for optimizing memory performance in a computer device or system. Still further, some aspects of the present invention relate to systems and methods for miniaturizing and optimizing memory layout on a circuit board.

Implementations of the present systems and methods can enable enhanced performance and miniaturized layout of memory and memory controllers. Accordingly, in some aspects, a circuit board is provided having a top and a bottom side. A memory controller is coupled to the circuit board along with a plurality of memory devices. To improve functionality and decrease footprint, the memory devices are soldered (or otherwise electrically connected) directly to the circuit board on both the top and bottom sides of the board. In this manner, each of the memory devices can be located within about 6.4 centimeters (about 2.5 inches) of the memory controller. Soldering can also provide a more robust connection than a DIMM socket, which can create a point of failure in the system. Thus, the removal of the DIMM can free up PCB real estate and increase system performance.

In some implementations, the representative system further includes a system clock that is electronically coupled to each of the plurality of memory devices via a clock line. Each of the plurality of electronic coupling clock lines is approximately of equal lengths to provide simultaneous clock signals to the memory devices. Additionally, in some implementations, each of the plurality of memory devices is electronically coupled to the memory controller via a separate data line. This direct connection eliminates the need for terminating resistors on the data lines, further reducing the footprint of the memory system. Furthermore, in some implementations, a representative system includes an address line that is in electronic communication with the memory controller and each of the plurality of memory devices.

In some implementations, a representative method provides soldering a plurality of memory devices directly to a PCB. In some instances, this includes locating each of the plurality of memory devices within about 6.4 centimeters (about 2.5 inches) from the memory controller. This includes disposing at least one of the memory devices on a top surface of the PCB, while disposing at least one of the memory devices on a bottom surface. In some implementations, one half of the memory devices are disposed on the top surface of the PCB and the other half on the bottom surface of the PCB. In some implementations, a representative method further provides electronically coupling each of the memory devices to the memory controller via a separate data line. In some implementations, a representative method further provides electronically coupling each of the memory devices to a system clock via a plurality of equidistant clock lines.

In some implementations, the present systems and methods enable both higher memory performance levels while miniaturizing PCB layout and substantially reducing the cost of the system. These results are enabled in part by the replacement of DIMM connector sockets with the soldering of memory devices directly to the PCB, on opposing sides of the PCB. The absence of the DIMM connector sockets can free up PCB real estate and avoid the need for DIMM terminating resistors, which in turn can free up additional real estate. Furthermore, in some instances, it is functionally advantageous and less expensive to include the maximum system memory fixedly on the PCB rather than providing memory scalability using DIMM sockets. Soldered memory devices can have enhanced impact and shock resistance over DIMM sockets, thus reducing the likelihood of device failure while providing a lock-tight system that can be incorporated into a more rugged environment. Furthermore, the removal of scalability and the reduction of line loss can allow system designers to optimize memory device performance, pushing memory devices to perform at their highest levels, and increasing system performance without increasing costs.

Turning now to IC connectors, some aspects of the current invention relate to IC interconnections. In particular, some aspect of the present invention relates to systems and methods for attaching an IC device to a circuit board. In particular, some aspects of the present invention relate to systems and methods for attaching an IC, which comprises an array of pins, to a circuit board through the use of an adaptor, which comprises a ball grid array, and which is configured to electrically and physically attach to the circuit board.

Generally, the adaptor, or interposer, includes a rigid, insulative casing having an array of machined pin sockets disposed therein. While the casing can have any suitable characteristic, in some cases, the casing has a substantially planar first surface and a substantially planar second surface, which is disposed opposite to the first surface. In some cases, one or more of the pin sockets in the array of machined pin sockets have a pin receptacle that opens at the casing's first surface and a solder ball that is disposed at the casing's second surface. Additionally, in some cases, each of the plurality of sockets includes two or more internal, resilient finger contacts. Thus, the adaptor is configured to electrically connect an integrated circuit having a PGA to a circuit board via a ball grid array.

While the methods and processes of the present invention have proven to be particularly useful in the area of physically and electrically connecting CPUs to PCBs, those skilled in the art can appreciate that the methods and processes can be used in a variety of different applications and in a variety of different areas of manufacture to attach any other suitable integrated circuit comprising a PGA to a circuit board. Indeed, according to some non-limiting examples, the described systems and methods electrically and physically connect a semi-conductor package, a memory chip, a processor chip, a northbridge, a southbridge, and/or any other suitable IC to a corresponding circuit board.

Finally, some aspects of the invention relate to LED circuitry. Specifically, some aspects relate to systems and methods for achieving activation of at least one multi-color LED, such as a bi-color or tri-color LED, using multiple electrical ground outputs or signals intended to activate only a single unicolor LED.

Implementation of such aspects of the present invention takes place in association with at least one multi-color LED, such as a bi-color or tri-color LED, being electrically connected such that the LED is capable of emitting each discrete color dictated by the LED's component materials and construction as a visual representation or indication of user desired information or a user defined status. In at least one implementation, a bi-color LED electrical indicator system includes a bi-color LED. In such implementations, the LED is capable of emitting two colors: a first color in accordance with current flow in one direction and a second color in accordance with current flow in the opposite direction. As with all diodes, the bi-color LED includes two leads or electrical terminals. However, one lead behaves as the cathode while the other lead behaves as the anode relative to the appropriate diode when the current flows in one direction. When the current is reversed though, the former cathode lead behaves as the anode and the former anode lead behaves as the cathode relative to the other diode.

In addition to the bi-color LED, some implementations of the foregoing system include a first electrical line providing an electrical ground output. In such implementations, the output is ordinarily intended to be connected to and to activate only a single independent unicolor LED. However, the first electrical line is connected to one lead of the bi-color LED and to a pull-up resistor. The pull-up resistor provides current flow in the appropriate direction for activating one of the bi-color LED's two possible colors.

Some implementations of the invention that relate to LED circuitry also include a second electrical line providing an electrical ground output similar to the first output discussed above. In like manner, the second electrical line is connected to the other lead of the bi-color LED and to another pull-up resistor. The pull-up resistor provides current flow in the appropriate direction for activating the other of the bi-color LED's two possible colors. In this manner, the bi-color LED's two discrete colors can both be activated at separate times according to the appropriate electrical output or signal.

While the methods, processes, systems, and apparatus of the present invention have proven to be particularly useful in the area of personal computing enterprises, those skilled in the art will appreciate that the methods, processes, system, and apparatus of the present invention can be used in a variety of different applications and in a variety of different areas of manufacture to yield customizable enterprises, including enterprises for any industry utilizing electronic systems. Examples of such industries include, but are not limited to, automotive industries, avionic industries, hydraulic control industries, auto/video control industries, telecommunications industries, medical industries, special application industries, and electronic consumer device industries. Accordingly, the methods, processes, systems, and apparatus of the present invention can provide improvements (such as massive computing power) to markets, including markets that have traditionally been untapped by current computer and electronic techniques.

These and other features and advantages of the present invention will be set forth or will become more fully apparent in the description that follows and in the appended claims. The features and advantages may be realized and obtained by means of the instruments and combinations particularly pointed out in the appended claims. Furthermore, the features and advantages of the invention may be learned by the practice of the invention or will be obvious from the description, as set forth hereinafter.

### BRIEF DESCRIPTION OF THE DRAWINGS

In order that the manner in which the above recited and other features and advantages of the present invention are obtained, a more particular description of the invention will be rendered by reference to specific embodiments thereof, which are illustrated in the appended drawings. Understanding that the drawings depict only typical embodiments of the present invention and are not, therefore, to be considered as limiting the scope of the invention, the present invention will be described and explained with additional specificity and detail through the use of the accompanying drawings in which:

FIG. 1 illustrates a representative system that provides a suitable operating environment for use of the present invention;

FIG. 2 illustrates a representative networked system configuration that may be used in association with embodiments of the present invention;

FIG. 3 illustrates a side view of a representative embodiment of power supply with components mounted on one side of a PCB;

FIG. 4 illustrates a side view of a representative embodiment of the miniaturized power supply with active components mounted on both sides of a PCB;

FIG. 5 illustrates a side view of a shielded trace, which can be used in the miniaturized power supply according to a representative embodiment of the present invention;

FIG. 6 illustrates a top view of a PCB design for the miniaturized power supply according to a representative embodiment of the present invention;

FIG. 7 illustrates a flow chart of a method for making the miniaturized power supply according to a representative embodiment of the present invention;

FIG. 8 illustrates a perspective view of a memory system layout according to a representative embodiment of the present invention;

FIG. 9 illustrates a top view of the memory system and system data lines according to a representative embodiment of the present invention;

FIG. 10 illustrates a block diagram view of system clock lines according to a representative embodiment of the present invention;

FIG. 11 illustrates a top view of a memory system layout and a system address line according to a representative embodiment of the present invention;

FIG. 12 illustrates a block diagram of a method for optimizing memory performance according to a representative embodiment of the present invention;

FIG. 13 illustrates a top-schematic view of a pin grid array to ball grid array adaptor according to a representative embodiment of the invention;

FIG. 14 illustrates a side-schematic view of the pin grid array to ball grid array adaptor according to a representative embodiment of the invention;

FIG. 15 illustrates a cross-sectional view of a machined pin socket disposed in a casing according to a representative embodiment of the invention;

FIG. 16 illustrates top view of the pin grid array to ball grid array adaptor according to a representative embodiment of the invention, wherein the adaptor is disposed on a PCB;

FIG. 17 illustrates a representative bi-color LED electrical circuit according to a representative embodiment of the invention; and

FIG. 18 illustrates a schematic view of a representative embodiment of PCB layout for some embodiments of an LED circuit.

### DETAILED DESCRIPTION OF THE INVENTION

The present invention relates to electronic systems and components. In particular, the present invention relates to miniaturization techniques, systems, and apparatus relating to power supplies, memory, interconnections, and LEDs.

In the disclosure and in the claims, the term array may refer to any suitable arrangement that comprises a plurality of adjacent rows and a plurality of adjacent columns.

The following disclosure of the present invention is grouped into five subheadings, namely “Representative Operating Environment,” “Power Supplies,” “Memory,” “IC Connectors,” and “Logic Chip/LED Connection.” The utilization of the subheadings is for convenience of the reader only and is not to be construed as limiting in any sense.

### Representative Operating Environment

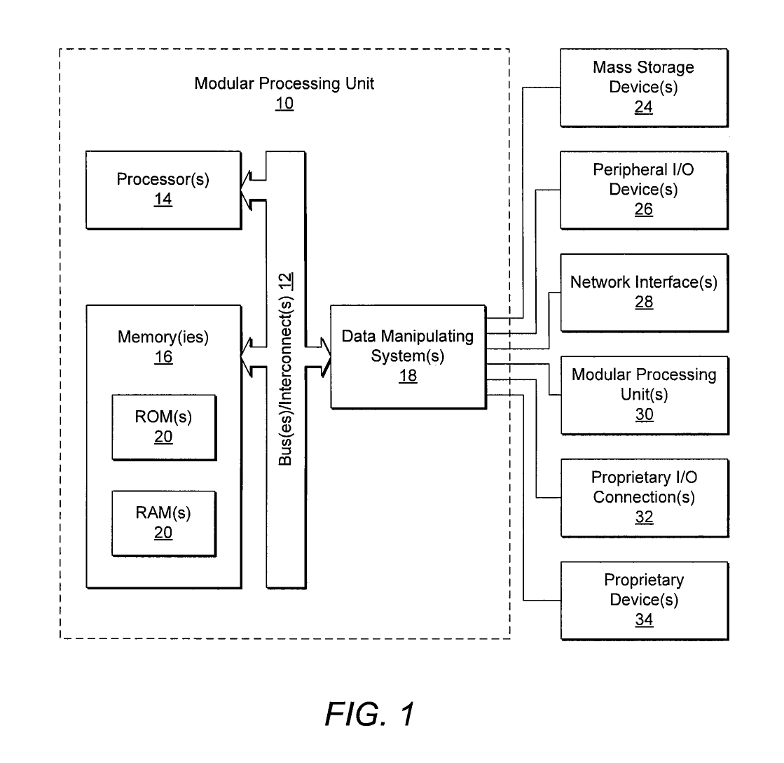

FIG. 1 and the corresponding discussion are intended to provide a general description of a suitable operating environment in accordance with embodiments of the present invention. As will be further discussed below, embodiments of the present invention embrace the use of one or more dynamically modular processing units in a variety of customizable enterprise configurations, including in a networked or combination configuration, as will be discussed below.

Embodiments of the present invention embrace one or more computer readable media, wherein each medium may be configured to include or includes thereon data or computer executable instructions for manipulating data. The computer executable instructions include data structures, objects, programs, routines, or other program modules that may be accessed by one or more processors, such as one associated with a general-purpose modular processing unit capable of performing various different functions or one associated with a special-purpose modular processing unit capable of performing a limited number of functions.

Computer executable instructions cause the one or more processors of the enterprise to perform a particular function or group of functions and are examples of program code means for implementing steps for methods of processing. Furthermore, a particular sequence of the executable instructions provides an example of corresponding acts that may be used to implement such steps.

Examples of computer readable media include random-access memory (“RAM”), read-only memory (“ROM”), programmable read-only memory (“PROM”), erasable programmable read-only memory (“EPROM”), electrically erasable programmable read-only memory (“EEPROM”), compact disk read-only memory (“CD-ROM”), any solid state storage device (e.g., flash memory, smart media, etc.), or any other device or component that is capable of providing data or executable instructions that may be accessed by a processing unit.

With reference to FIG. 1, a representative enterprise includes modular processing unit 10, which may be used as a general-purpose or special-purpose processing unit. For example, modular processing unit 10 may be employed alone or with one or more similar modular processing units as a personal computer, a notebook computer, a personal digital assistant (“PDA”) or other hand-held device, a workstation, a minicomputer, a mainframe, a supercomputer, a multi-processor system, a network computer, a processor-based consumer device, a cellular phone, a smart appliance or device, a control system, or the like. Using multiple processing units in the same enterprise provides increased processing capabilities. For example, each processing unit of an enterprise can be dedicated to a particular task or can jointly participate in distributed processing.

In FIG. 1, the modular processing unit 10 includes one or more buses and/or interconnects 12, which may be configured to connect various components thereof and enables data to be exchanged between two or more components. The bus(es)/interconnect(s) 12 may include one of a variety of bus structures, including a memory bus, a peripheral bus, or a local bus that uses any of a variety of bus architectures. Typical components connected by the bus(es)/interconnect(s) 12 include one or more processors 14 and one or more memories 16. Other components may be selectively connected to the bus(es)/interconnect(s) 12 through the use of logic, one or more systems, one or more subsystems and/or one or more I/O interfaces, hereafter referred to as “data manipulating system(s) 18.” Moreover, other components may be externally connected to the bus(es)/interconnect(s) 12 through the use of logic, one or more systems, one or more subsystems and/or one or more I/O interfaces, and/or may function as logic, one or more systems, one or more subsystems, and/or one or more I/O interfaces, such as one or more modular processing unit(s) 30 and/or proprietary device(s) 34. Examples of I/O interfaces include one or more mass storage device interfaces, one or more input interfaces, one or more output interfaces, and the like. Accordingly, embodiments of the present invention embrace the ability to use one or more I/O interfaces and/or the ability to change the usability of a product based on the logic or other data manipulating system employed.

The logic may be tied to an interface, part of a system, subsystem and/or be used to perform a specific task. Accordingly, the logic or other data manipulating system may allow, for example, for IEEE1394 (firewire), wherein the logic or other data manipulating system is an I/O interface. Alternatively or additionally, logic or another data manipulating system may be used that allows a modular processing unit to be tied into another external system or subsystem. For example, an external system or subsystem that may or may not include a special I/O connection. Alternatively or additionally, logic or another data manipulating system may be used wherein no external I/O is associated with the logic. Embodiments of the present invention also embrace the use of specialty logic, such as for ECUs for vehicles, hydraulic control systems, etc. and/or logic that informs a processor how to control a specific piece of hardware. Moreover, those skilled in the art will appreciate that embodiments of the present invention embrace a plethora of different systems and/or configurations that utilize logic, systems, subsystems and/or I/O interfaces.

As provided above, embodiments of the present invention embrace the ability to use one or more I/O interfaces and/or the ability to change the usability of a product based on the logic or other data manipulating system employed. For example, where a modular processing unit is part of a personal computing system that includes one or more I/O interfaces and logic designed for use as a desktop computer, the logic or other data manipulating system can be changed to include flash memory or logic to perform audio encoding for a music station that wants to take analog audio via two standard RCAs and broadcast them to an IP address. Accordingly, the modular processing unit may be part of a system that is used as an appliance rather than a computer system due to a modification made to the data manipulating system(s) (e.g., logic, system, subsystem, I/O interface(s), etc.) on the back plane of the modular processing unit. Thus, a modification of the data manipulating system(s) on the back plane can change the application of the modular processing unit. Accordingly, embodiments of the present invention embrace very adaptable modular processing units.

As provided above, processing unit 10 includes one or more processors 14, such as a central processor (or CPU) and optionally one or more other processors designed to perform a particular function or task. It is typically the processor 14 that executes the instructions provided on computer readable media, such as on the memory(ies) 16, a magnetic hard disk, a removable magnetic disk, a magnetic cassette, an optical disk, or from a communication connection, which may also be viewed as a computer readable medium.

The memory(ies) 16 includes one or more computer readable media that may be configured to include or includes thereon data or instructions for manipulating data, and may be accessed by the processor(s) 14 through the bus(es)/interconnect(s) 12. The memory(ies) 16 may include, for example, ROM(s) 20, used to permanently store information, and/or RAM(s) 22, used to temporarily store information. The ROM(s) 20 may include a basic input/output system (“BIOS”) having one or more routines that are used to establish communication, such as during start-up of the modular processing unit 10. During operation, the RAM(s) 22 may include one or more program modules, such as one or more operating systems, application programs, and/or program data.

As illustrated, at least some embodiments of the present invention embrace a non-peripheral encasement, which provides a more robust processing unit that enables use of the unit in a variety of different applications. In FIG. 1, one or more mass storage device interfaces (illustrated as data manipulating system(s) 18) may be used to connect one or more mass storage devices 24 to the bus(es)/interconnect(s) 12. The mass storage devices 24 are peripheral to the modular processing unit 10 and allow the modular processing unit 10 to retain large amounts of data. Examples of mass storage devices include hard disk drives, magnetic disk drives, tape drives and optical disk drives.

A mass storage device 24 may read from and/or write to a magnetic hard disk, a removable magnetic disk, a magnetic cassette, an optical disk, or another computer readable medium. The mass storage devices 24 and their corresponding computer readable media provide nonvolatile storage of data and/or executable instructions that may include one or more program modules, such as an operating system, one or more application programs, other program modules, or program data. Such executable instructions are examples of program code means for implementing steps for methods disclosed herein.

The data manipulating system(s) 18 may be employed to enable data and/or instructions to be exchanged with the modular processing unit 10 through one or more corresponding peripheral I/O devices 26. Examples of the peripheral I/O devices 26 include input devices such as a keyboard and/or alternate input devices, such as a mouse, trackball, light pen, stylus, or other pointing device, a microphone, a joystick, a game pad, a satellite dish, a scanner, a camcorder, a digital camera, a sensor, and the like, and/or output devices such as a monitor or display screen, a speaker, a printer, a control system, and the like. Similarly, examples of the data manipulating system(s) 18 coupled with specialized logic that may be used to connect the peripheral I/O devices 26 to the bus(es)/interconnect(s) 12 include a serial port, a parallel port, a game port, a universal serial bus (“USB”), a firewire (IEEE 1394), a wireless receiver, a video adapter, an audio adapter, a parallel port, a wireless transmitter, any parallel or serialized I/O peripherals or another interface.

The data manipulating system(s) 18 enable an exchange of information across one or more network interfaces 28. Examples of the network interfaces 28 include a connection that enables information to be exchanged between processing units, a network adapter for connection to a local area network (“LAN”) or a modem, a wireless link, or another adapter for connection to a wide area network (“WAN”), such as the Internet. The network interface 28 may be incorporated with or peripheral to modular processing unit 10, and may be associated with a LAN, a wireless network, a WAN and/or any connection between processing units.

The data manipulating system(s) 18 enable the modular processing unit 10 to exchange information with one or more other local or remote modular processing units 30 or computer devices. A connection between modular processing unit 10 and modular processing unit 30 may include hardwired and/or wireless links. Accordingly, embodiments of the present invention embrace direct bus-to-bus connections. This enables the creation of a large bus system. It also eliminates hacking as currently known due to direct bus-to-bus connections of an enterprise. Furthermore, the data manipulating system(s) 18 enable the modular processing unit 10 to exchange information with one or more proprietary I/O connections 32 and/or one or more proprietary devices 34.

Program modules or portions thereof that are accessible to the processing unit may be stored in a remote memory storage device. Furthermore, in a networked system or combined configuration, the modular processing unit 10 may participate in a distributed computing environment where functions or tasks are performed by a plurality of processing units. Alternatively, each processing unit of a combined configuration/enterprise may be dedicated to a particular task. Thus, for example, one processing unit of an enterprise may be dedicated to video data, thereby replacing a traditional video card, and provides increased processing capabilities for performing such tasks over traditional techniques.

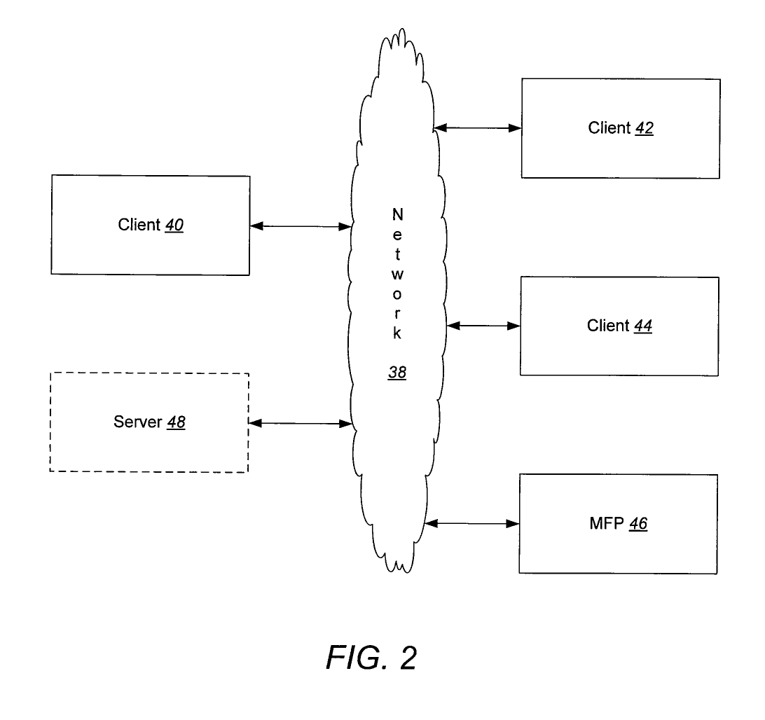

While those skilled in the art will appreciate that the invention may be practiced in networked computing environments with many types of computer system configurations, FIG. 2 represents an embodiment of the present invention in a networked environment that includes clients connected to a server via a network. While FIG. 2 illustrates an embodiment that includes two clients connected to the network, alternative embodiments include one client connected to a network or many clients connected to a network. Moreover, embodiments in accordance with the present invention also include a multitude of clients throughout the world connected to a network, where the network is a wide area network, such as the Internet.

### Power Supplies

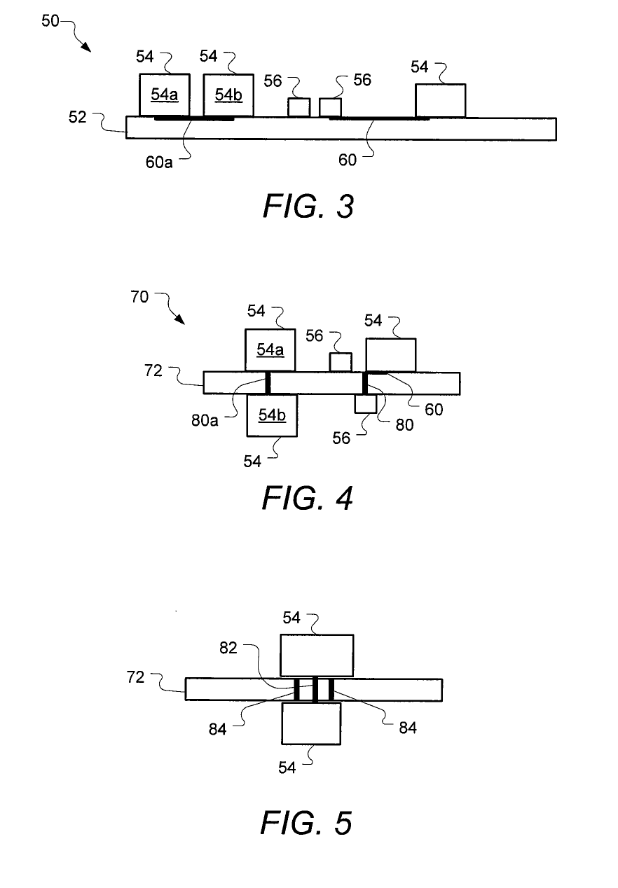

Some aspects of the present invention relate to power supplies. As introduced above, many conventional power supply designs are often not very space efficient. A power supply can include a plurality of electronic components, which can include active components and passive components. Active components include parts, such as switches (e.g., bipolar transistors, field effect transistors, etc,), regulators, comparators, and the like. Passive components include parts, such as resistors, inductors, capacitors, and the like. Electronic components are typically mounted on a PCB, and interconnected through traces on the PCB. Typically, the electronic components are mounted on only one side of the PCB. This is viewed as desirable in the electronics industry for cost considerations. In some instances, passive components (e.g., small capacitors or small resistors) are occasionally placed on the opposite side of the board. For example, FIG. 3 illustrates a power supply, shown generally at 50, where a PCB 52 has a plurality of components 54 and 56 mounted on one side 58 of the PCB (or other circuit board). The components can include active components 54 and passive components 56. Interconnections between the components are provided by traces 60 (e.g., conductive material attached to or deposited on a non-conductive substrate). The PCB can be, for example, a multilayer PCB providing multiple layers of traces (not shown).

A miniaturized power supply, in accordance with some embodiments of the invention, is shown in FIG. 4. In contrast to a conventional power supply, the miniaturized power supply 70 can include active components 54 placed on both sides of a PCB 72. Accordingly, some active components can be placed directly opposite each other in some embodiments. In other embodiments, active components can be opposite each other and partly overlapping. Passive components 56 can also be placed on one or both sides of the PCB. Traces 60 and vias 80 can interconnect the components.

Several benefits can be obtained by mounting components on both sides of the PCB 72. For example, interconnection distances between components can be reduced. For example, considering a first component 54a and a second component 54b, these components cannot be placed substantially closer than shown in FIG. 3 when on the same side of the PCB. For example, some spacing is typically required between components to allow for component size tolerances and access for a pick and place machine. Thus, trace 60a interconnecting a terminal of the first component to a terminal of the second component must generally have a length equal or greater than the horizontal dimension of the components. For example, to interconnect two components having horizontal lengths of about 0.64 centimeters (about 0.25 inches), the trace must be at least about 0.64 centimeters (about 0.25 inches) in length.

In contrast, when the components 54a, 54b are placed opposite each other on opposite sides of the PCB 72, the trace length can be significantly shorter. For example, the components can be placed so that the terminals are directly opposite each other, making the trace length essentially the length of the via 80a interconnecting the components to each other (there can be additional length due to, for example, a pad). For a PCB 72 having a thickness of about 0.13 centimeters (about 0.05 inches), the trace length is thus about 0.13 centimeters (about 0.05 inches) in length—a reduction of a factor of about five.

The reduction in trace length provided in some embodiments of the invention can provide multiple benefits. For example, while an ideal electrical interconnection has zero resistance, zero capacitance, and zero inductance, actual traces will exhibit some parasitic resistance, capacitance, and inductance (RLC). While the parasitic RLC of a trace is a function of various parameters (e.g., board thickness, conductive material thickness, dielectric constant of insulating substrate, proximity of other traces, etc.), there is a significant dependence of parasitic RLC on the length of a trace. Generally, the parasitic RLC increases linearly with the length of the trace. Accordingly, by reducing trace length, the parasitic RLC can be reduced, which in turn allows the electrical connections to behave more like ideal (e.g., zero RLC) interconnections. In some cases, the reduced parasitic RLC can require adjustment of the component values. For example, a circuit design may require a certain amount of inductance. In a one-sided design, this required inductance may be provided in part by a component and in part by parasitic inductance of the PCB 52. In the two-sided designed, with the reduced parasitic inductance provided by the PCB 72, the component inductance may therefore be reduced. As another example, in a one-sided design, a component value may be required to compensate for parasitic RLC, and thus the component value may be reduced or the component entirely eliminated in the two-sided design due to the reduced parasitic RLC.

Another benefit of reduced trace length is reduced noise emission and reduced noise susceptibility. An electrical interconnection can emit noise, both through radiated and non-radiated electromagnetic coupling. In general, the amount of noise coupling is increased for longer electrical interconnections. For example, longer traces can have higher mutual capacitance or inductance between each other, providing for higher coupling through electromagnetic fields. Longer traces can also act more effectively as an antenna, emitting or collecting energy from adjacent traces through propagating electromagnetic waves. Accordingly, by reducing trace length, noise coupling can also be reduced.

In some instances, the trace lengths in the two-sided design can be sufficiently short that shielding that would otherwise be needed can be eliminated. In other cases, the area lost due to shielding can be significantly reduced. For example, FIG. 5 illustrates a shielded connection between two components 54 mounted on opposite sides of a PCB 72. The shielded connection comprises a signal conductor 82 electrically connecting the two components and surrounded by a plurality of shield structures 84. The shield structures can include, for example, vias and/or traces which connect to a ground plane. It can be seen that the shield structures are entirely contained within the footprint of the components, and thus do not require any additional PCB area beyond that already covered by the components. Shielded connections can be used for electrical connections which are particularly sensitive to picking up noise and for electrical connections which are particularly prone to emitting noise. While the shielded connection shown in FIG. 5 is in the vertical direction (using vias for the signal conductor and shield structures), shielded connections can also be provided in the horizontal direction (using traces for the signal conductor and shield structures), or using combinations of both.

An additional benefit of the shortened trace lengths is the reduced amount of board area consumed by the traces. This area can be used in various beneficial ways. For example, trace widths can be increased. In general, wider trace widths can provide for lower resistance and inductance, in turn providing for higher current handling capability.

The power supply can also make effective use of interconnection planes. For example, an interconnection plane can consist of an essentially continuous plane (e.g., continuous over a defined two-dimensional area extent except for clearance holes) of conductive material disposed on an exterior or interior layer of the PCB 72. For example, a ground plane can be used for connecting ground terminals of two or more components together. As another example, a power plane can be used for connecting power terminals of two or more of components together. An interconnection plane can beneficial because it provides a low resistance and low inductance interconnection between the components tied to the plane. When necessary, holes can provided in the plan to provide clearance for vias (e.g., for signal interconnections) to pass through the plane without electrically connecting to the plane.

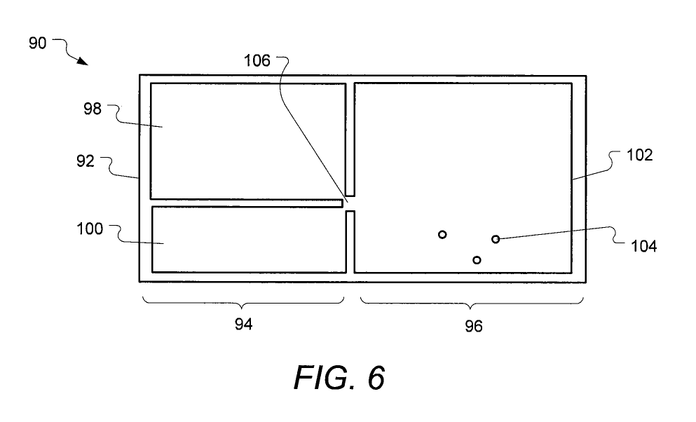

In some instances, it can be beneficial to provide one or more split planes which are interconnected to each other at a single point. For example, FIG. 6 illustrates a PCB design 90 for an electronic system in which the PCB 92 includes a power supply portion 94 and an operational circuit portion 96. Multiple split plane sections 98, 100, and 102 are provided. The split planes can be, for example, a conductive layer disposed on an exterior or interior layer of the PCB which has cut away or etched portions to define the split planes. The operational circuitry comprises a split plane section 102 which is contiguous underneath the operational circuitry (except for via clearance holes 104). The power supply portion comprises two split plane sections 98 and 100. The plane portions are each connected to each other via single point of connection 106. Use of multiple split planes can be beneficial at keeping noise generated within the power supply confined within the power supply, and for keeping noise sensitive portions of the power supply (e.g., disposed over and under plane 98) isolated from noise generating portions of the power supply (e.g., portions disposed over and under plane 100).

Additional miniaturization of a power supply can be obtained by optimizing the amount and type of capacitors. Capacitors can serve several purposes in a power supply. Capacitors can provide charge storage between cycles of the power supply (e.g., cycles of the alternating current input in a linear supply, or during switching cycles in a switching power supply). Capacitors can also provide energy storage to meet surge current demands (e.g., which occur too fast for a regulator to respond to). Capacitors can also provide for noise filtering (e.g., shunting noise signals to ground). Typically, power supplies are designed with a large amount of capacitance in excess of that required for charge storage under normal operating conditions. This excess capacitance is provided in part, due to the non-ideal response of large capacitors (e.g., equivalent series resistance) which limits the effectiveness of the capacitors.

In contrast, it has been determined by the present inventors that the total capacitance provided can be reduced by using a mixture of capacitor types. For example, a total capacitance requirement can be determined based on the requirements of the operational circuitry supplied by the power supply and the characteristics of the power supply. The total capacitance requirement can then be partitioned into different types of capacitors. Some small, low equivalent series resistance (ESR) capacitors can be provided. The low ESR capacitors can respond quickly to rapid changes in load, but provide a limited ability to store charge. Use of all low ESR capacitors to provide the total capacitance requirement would be impractical, however, due to the size and cost of the low ESR capacitors. Thus, additional capacitors can be provided which have a higher ESR. The higher ESR capacitors, while responding slower, can respond when the load variation exceeds the capability of the low ESR capacitors. Thus, the total capacitance requirement can be met in part by low ESR capacitors and in part by high ESR capacitors. If desired, the total capacitance requirement can be partitioned into two or more types of capacitors. As a particular example, a total capacitance requirement of 1 Farad can be partitioned into 100 milliFarad of low ESR capacitors, 400 milliFarad of medium ESR capacitors, and 0.5 Farad of high ESR capacitors.

By partitioning the total capacitance requirement in such a manner, the total capacitance can be reduced relative to a conventional design, in turn providing for reduced board area usage. Moreover, it has been observed that the total amount of capacitance required can generally be reduced as compared to a conventional design which uses all medium or high ESR capacitors.

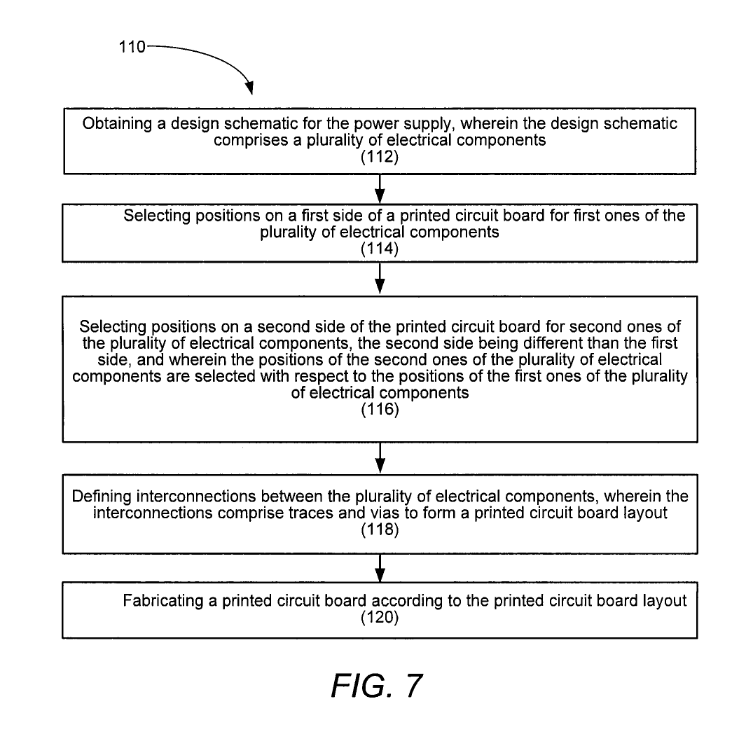

Making a miniaturized power supply can proceed in any suitable manner, including according to the flow chart illustrated in FIG. 7. The method 110 can begin at box 112 with obtaining a design schematic for the power supply. For example, the design schematic can be developed by engineers. The design schematic can be, for example, based on a reference design provided by a component manufacturer or can be a customized design.

The design schematic can include a parts list defining the components composing the power supply, and a net list defining interconnections between the components. The design schematic can be in an electronic form. The design schematic can be in a form which is usable by computer automatic design (“CAD”) systems, such as an industry standard file format.

Boxes 114 and 116 show the method 110 can continue by selecting positions on the first and second sides of the PCB for first and second ones of a plurality of electrical components. The layout of the PCB can be determined using a CAD layout tool. Using the CAD layout tool, positions for the components on a PCB can be defined. For example, first ones of the electronic components can be positioned on a first side of the PCB and second ones of the electronic components can be positioned on a second side of the PCB. The positions of the second ones of the electronic components can be related to the positions of the first ones of the electronic components as will now be described.

Various aspects can be taken into consideration when positioning the electronic components. Components can be positioned relative to each other to minimize trace lengths. Relative importance of trace lengths can be considered as well, with compromises made to keep critical traces (e.g., traces corresponding to interconnections which are susceptible to noise or highly likely to emit noise) shorter at the expense of making non-critical traces longer. For example, sensing lines tend to be particularly sensitive to noise, and thus can be kept away from other traces or shielded. As a particular example, sense lines can be used by sensing circuitry in the power supply to detect over current and over/under voltage conditions. Noise pickup by the sense lines can result in spurious detections, resulting in undesired shut down of the power supply.

Components can be positioned relative to each other on opposite sides of the board to allow vias to serve multiple purposes. For example, conventional one-sided PCBs often include vias to provide connections between traces on the top side and the bottom side (and, when present, traces on internal layers) of the PCB. In the miniaturized power supply, components can also be positioned on the opposite side of the PCB to allow vias to serve multiple purposes. For example, a via used to connect a trace on the top side to the bottom side can also be used to connect to a part on the bottom side.

When positioning parts on the second side relative to the first side, consideration of the position of parts need not exclusively focused on interconnection length. For example, noise susceptible components can be kept away from noise generating components.

When laying out the miniaturized power supply, the selecting of locations can be viewed as a three dimensional positioning task. In other words, the locations of components can be defined in X, Y, and Z dimensions, wherein X and Y correspond to lateral dimensions on the PCB (within the plane defined by the PCB, e.g., “left/right”) and the Z dimension corresponds to a vertical dimension on the PCB (normal to the plane defined by the PCB, e.g., “up” and “down”). Positions can be defined relative to a reference point on the PCB. This is in contrast to a conventional single sided PCB design which merely positions in X and Y dimensions.

Once the components are positioned, box 118 shows that the interconnections can be defined. For example, the interconnections can include pads (for electrical connections to terminals of the components), traces, and vias. The positions of pads, traces, and vias can be defined relative to the reference point. Routing of interconnections can be performed, for example, using an automated routing tool. A PCB layout, defining the positions of the pads, traces, and vias, can be provided in an electronic form from the CAD system. For example, the PCB layout can be defined in an industry standard format useable for fabrication of PCBs. PCBs can be fabricated according to the PCB layout. As shown at box 120, a power supply can be constructed from the fabricated PCB by mounting and electrically connecting components to the PCB.

Miniaturized power supplies in accordance with some embodiments of the present invention provide benefits in reduced area consumption. For example, in some embodiments, PCB area has been reduced from approximately 10.2 square centimeters (approximately 4 square inches) for a conventional single-sided design to approximately 2.5 square centimeters (approximately 1 square inch) or less for a two-sided design.

Surprisingly, additional benefits in improved performance have also been observed in some embodiments. For example, due to the reduced trace lengths and reduced interaction between traces, improved noise performance has been observed. In particular, stability of regulation and output noise of the miniaturized power supply has been observed to be significantly improved as compared to a conventional one-sided PCB design. In general, the improved efficiencies in space and performance can be enough to offset the additional manufacturing (and repair) costs associated with placing active parts on both sides of the PCB.

As will now be appreciated, miniaturized power supplies in accordance with the present disclosure can help to provide more area efficient, higher performance power supplies. Such power supplies can be particularly useful in area constrained applications, such as compact computing systems, embedded computers, laptop computers, and similar applications.

Thus, as discussed herein, at least some aspects of the present invention embrace techniques for miniaturization of power supplies. In particular, at least some aspects of the invention relate miniaturized power supplies which make effective utilization of PCB area.

### Memory

Some aspects of the present invention relate to systems and methods for optimizing memory performance in a computer device or system. Still further, the some aspects of the present invention relate to systems and methods for miniaturizing and optimizing memory layout on a circuit board.

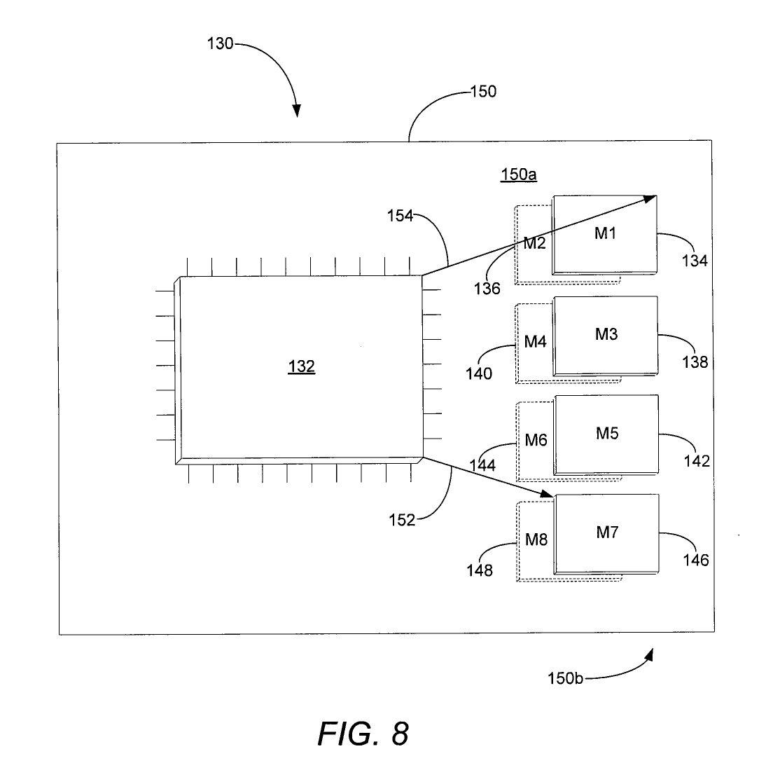

Referring now to FIG. 8, which depicts a PCB layout of a memory system 130 having a memory controller 132 and a set of eight memory devices 134, 136, 138, 140, 142, 144, 146, and 148 (also labeled M1-M8). Each of the eight memory devices is soldered or otherwise electrically coupled directly to the PCB 150. Four memory devices M1, M3, M5, and M7 are soldered to the top surface of the PCB 150a and four others M2, M4, M6, and M8 are soldered to the bottom surface 150b (not directly shown) (these devices are illustrated a dotted lines to represent their being on the bottom surface 150b of the PCB 150). This direct connection is a deviation from certain prior memory connections having a DIMM with one or more connecting slots. In those devices, memory was soldered to memory cards, which were inserted into the DIMM. Accordingly, the representative embodiment removes this indirect connection, which eliminates the need for a DIMM and corresponding circuitry.

By removing the DIMM, the memory devices can be located much closer to the memory controller 132. Accordingly, in at least some embodiments a portion of each memory devices is located within a distance 152 of approximately 6.4 centimeters (approximately 2.5 inches) or less from the memory controller 152. This distance 152, enables a more compact, optimized PCB layout that enables a memory system to be placed into more compact devices, such as handheld and miniaturized computer systems. Furthermore, in some embodiments, the entire memory device is located within the distance 154 of approximately 6.4 centimeters (approximately 2.5 inches) or less from the memory controller 132.

As stated, the memory devices M1-M8 are soldered directly to the PCB. Soldered memory device have enhanced impact and shock resistance over DIMM sockets, thus reducing the likelihood of device failure while providing a lock-tight system that can be incorporated into a more rugged environment. When memory is soldered to a memory card that is inserted into a DIMM slot, the connection between the memory card and the slot is weak and reduced the versatility of the entire computer system. Accordingly, the present system with its soldered memory devices enables the entire PCB to be incorporated into a computer device or system designed to resist high impacts and more rugged environments than the traditional desktop computer system, such as automobile computer systems.

In addition to adding physical strength and an optimized layout, the soldered memory devices remove the uncertainty of a scalable memory system. Fixing the memory devices M1-M8 to the PCB 150 enables system designers to optimize memory device performance, pushing memory devices to perform at higher levels, thus increasing system performance without increasing costs.

Furthermore, in light of the recent trend of lowering memory device cost, in at least some embodiments, it is economically feasible to include the maximum usable memory on the PDB, rather than providing memory scalability using DIMM connector sockets. In at least some embodiments, it is now feasible to initially install the maximum foreseeable system memory directly usable by the host computer system onto the device. This eliminates the need for the scalable DIMM, the cost of such parts, the size of such parts, as wells as the corresponding design uncertainty.

With continuing reference to FIG. 8, in the representative embodiment the system 130 includes a plurality of memory devices soldered directly to the PCB 150 in proximity to the memory controller 132. In some embodiments, the memory devices are disposed on both the top 150a and bottom 150b surface of the PCB 150 to maximize PCB space. Accordingly, in some embodiments, memory devices on the top surface 150a of the PCB are directly above the memory devices that are on the bottom surface 150b. In other embodiments, the memory devices on the top surface are staggered from the memory devices that are on the bottom surface. As shown, the memory devices are disposed in a straight line. However, in other embodiments, the memory devices are clustered in a group, disposed around the memory controller 132, arranged in multiple lines, or otherwise situated near the memory controller 132.

In some embodiments, the individual memory devices M1-M8 are DRAM memory which may, in combination, form the main memory (the “RAM”) of a personal computer. DRAM is a type of random access memory that stores each bit of data in a separate capacitor within an integrated circuit. Since real capacitors leak charge, the information eventually fades unless the capacitor charge is refreshed periodically. Because of this refresh requirement, it is a dynamic memory as opposed to SRAM and other static memory. DRAM memory devices can be manufactured to be very small, which enable an optimized PCB layout, and small PCB footprints. In other embodiments, the memory devices include SRAM, TRAM, ZRAM, and/or TTRAM memory. Still in other embodiments, the system includes non-volatile memory devices, such as EEPROM memory, or flash memory.

Based on the needs of the memory system, the individual memory devices M1-M8 have varying storage capacities. In some embodiments, the individual memory devices have a 128 MB, a 256 MB, a 512 MB, a 1 GB, etc. storage capacity. Additionally, while FIG. 8 illustrates eight memory devices, more or less memory devices can be included in the system. For example, two, three, four, six, ten, or more memory devices can be included in the system.

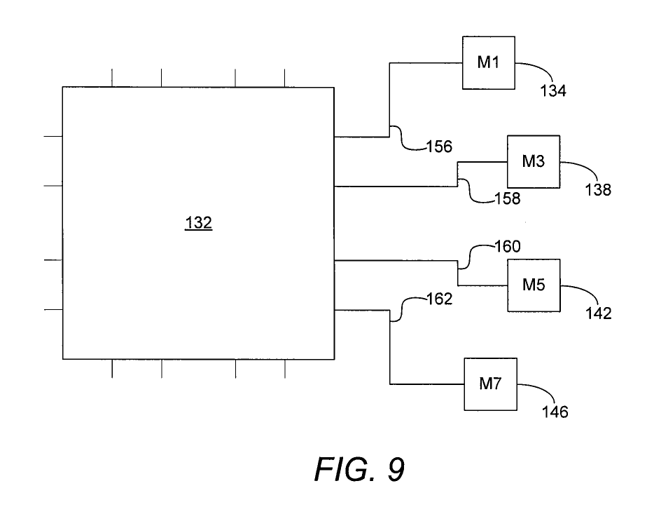

The memory system 130 of FIG. 8 includes lines that form electrical connections between the memory controller 132 and/or other devices of the computer system. For clarity, these lines are not illustrated in FIG. 8. FIGS. 9-11 illustrate representative embodiments of the system data lines, clock lines, and address lines, which may be incorporated into the system 130 shown in FIG. 8. Referring now to FIG. 9, the memory system 130 is depicted having a set of data lines 156, 158, 160, and 162. As will be understood by those of skill in the art, each illustrated data line can represent multiple data lines, such as 16, 32, 64, etc. Providing each memory device with a separate, direct data line eliminates the need for a terminating resistor on the end of the data line, as is required in series connections. Furthermore, the direct connection also eliminates the need for a trace resistor along the data line. Thus, these direct connections require only minimal PCB real estate. Subsequently, this configuration allows the memory devices M1-M8 to be positioned close to the memory controller 132 since they occupy limited space therebetween.

Direct, individual data lines provide advancement over DIMM data lines, which connect the DIMM slots in series and require terminating resistors on the end of each line. In this configuration, DIMMs require more space on the PCB as well as more parts. Accordingly, embodiments of the present system eliminate these space requirements and thus decrease both the cost and size of the resulting system.

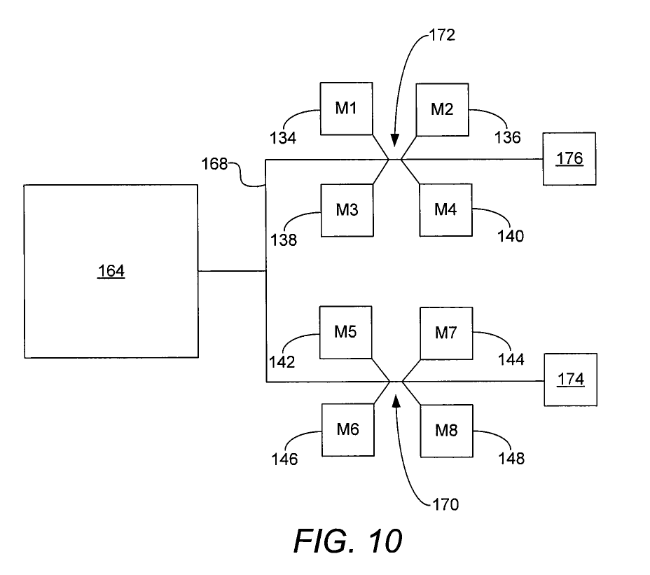

Referring now to FIG. 10, a set of clock lines (represented collectively at 168) is depicted, which prove electrical communication between the system clock 164 and the individual memory devices M1-M8. FIG. 10 is a block diagram that illustrates graphically representative clock line paths and lengths. However, it will be understood that FIG. 10 does not accurately represent a complete layout of the PCB since in accordance with at least some embodiments of the present invention, at least some memory devices may be disposed on the opposite side of the PCB, as is illustrated in FIG. 8.

Clock signals synchronize the memory devices and allow the entire system to operate properly and rapidly. Accordingly, clock signals from the system clock should arrive simultaneously at each memory device. Thus, in some embodiments, the length of the lines between the system clock 164 and the individual memory devices (e.g., M1-M8) are equidistant (or substantially equidistant). A starburst configuration 170 and 172 enables the line from the system clock to be divided into multiple lines each having an equal distance. The lines proceeding from the starburst configurations 170 and 172 connect to the memory devices and provide a clock signal thereto. By disposing the center of the starburst at a point equidistant from each memory device, the starburst properly and accurately transmits a synchronized clock signal to the memory devices M1-M8. In some embodiments, the starburst configurations 170 and 172 each include a terminator resistor 174 and 176 in parallel with the memory devices to ensure proper function.

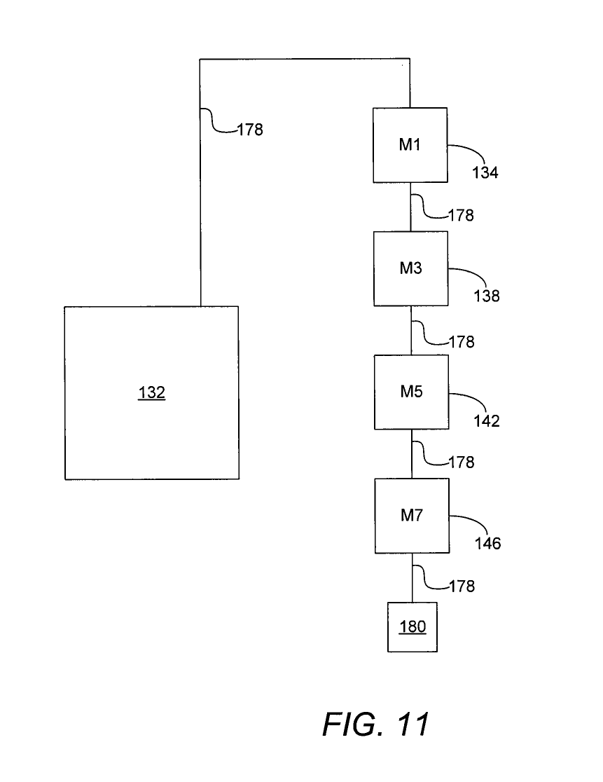

Referring now to FIG. 11, which illustrates an address line 178 in electrical communication with each of the memory devices M1, M3, M5, and M7 (also M2, M4, M6, and M8, which are not shown) and the memory controller 132. The address line connects the memory devices in series and provides electrical signals between the memory controller 132 and the memory devices during reading and writing memory operations. In some embodiments, a terminator resistor 180 is connected at the end of the addressing line to improve system functionality.

The routing of memory system lines, in particular the data, clock, and address lines enable a compact and optimized memory system layout that, in some embodiments, enables each memory device to be disposed within two and a half inches or less of the memory controller 132. Furthermore, the configuration and orientation of system lines reduces the requirement for additional components, while providing highly optimized memory performance.

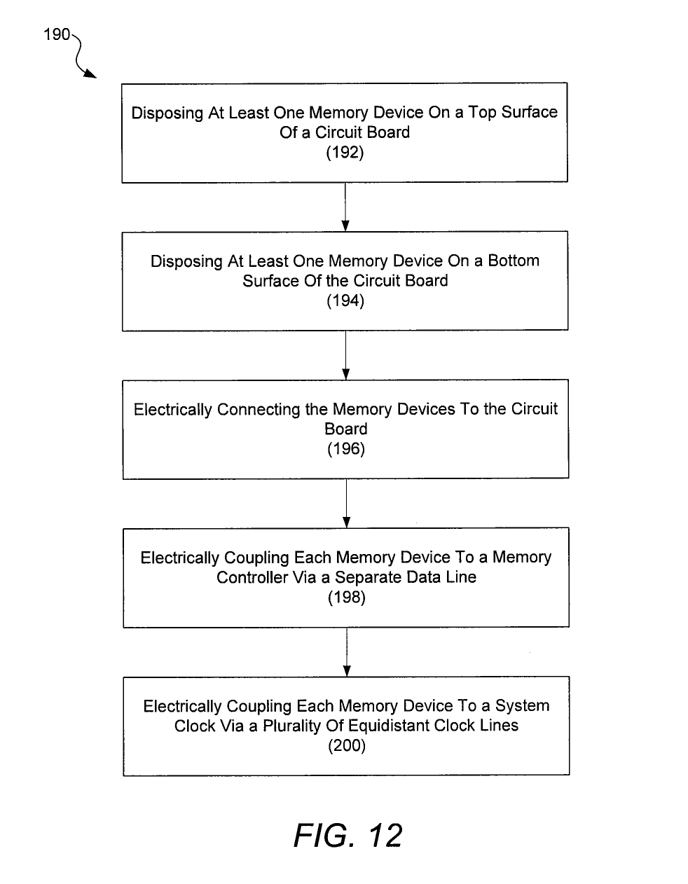

Referring now to FIG. 12, a block diagram of a method 190 for optimizing a memory system is illustrated, according to one representative embodiment. The representative method provides (at box 102) disposing at least one memory device on a top surface of a circuit board. Additionally, box 194 shows the method can progress as at least one memory device is disposed on the bottom surface of the circuit board. At box 196, FIG. 12 shows the memory devices are then soldered directly to the circuit board. In some embodiments, memory devices are placed 6.4 centimeters (2.5 inches) or less from the memory controller. In some embodiments, soldering includes disposing at least one of the memory devices on a top surface of the PCB, while disposing at least one of the memory devices on a bottom surface. The method 190 (as shown at box 198) further provides electronically coupling each of the memory devices to the memory controller via a separate data line. Lastly, box 200 shows the method 190 provides electronically coupling each of the memory devices to a system clock via a plurality of equidistant clock lines.

Thus, embodiments of the present invention relate to computer circuit board layouts. In particular, at least some aspects of the present invention relate to systems and methods for optimizing memory performance in a computer device or system. Still further, at least some aspects of the present invention relate to systems and methods for miniaturizing and optimizing memory layout on a circuit board.

### IC Connectors

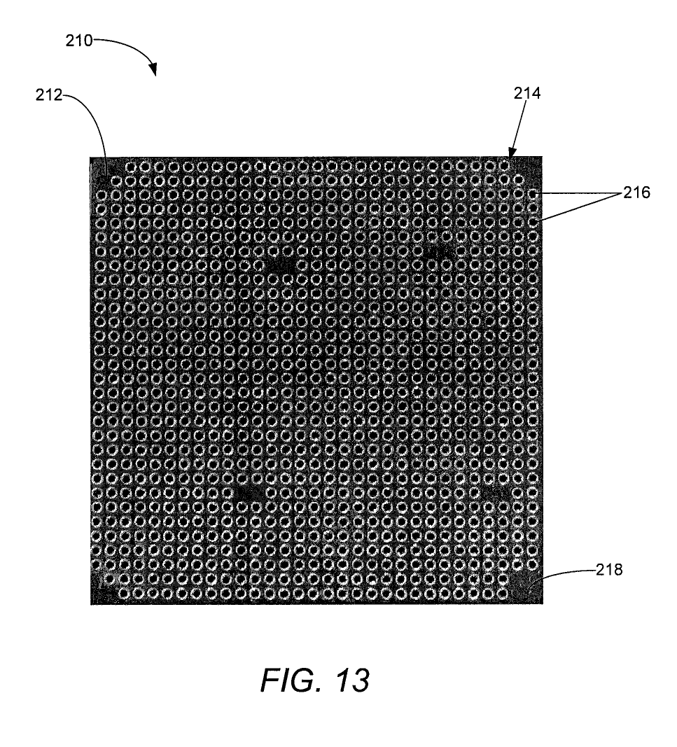

Some aspects of the invention relate to IC Connectors. In particular, some aspects of the invention relate to a PGA to BGA adaptor that can attach an IC (e.g., a CPU) to a circuit board (e.g., a PCB). The described PGA to BGA adaptor can comprise any suitable component that allows it to electrically and physically connect an IC device comprising a PGA to a circuit board through the use of a solder BGA. By way of non-limiting example, FIG. 13 illustrates a representative embodiment in which the PGA to BGA adaptor 210 comprises a casing 212 and an array 214 of machined pin sockets 216. In order to provide a better understanding of the described adaptor, each of its aforementioned components is described below in more detail.

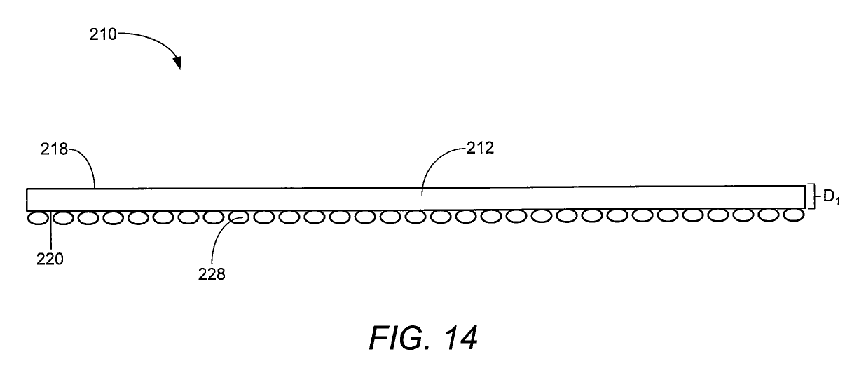

With respect to the casing 212, the casing can comprise any suitable characteristic that allows it to insulate the machined pin sockets 216 while housing the pin sockets in such a manner that allows the pin sockets to electrically connect pins, from an integrated circuit, to a circuit board. In one non-limiting example, FIGS. 13 and 14 show embodiments in which the casing 212 comprises a first surface 218 and a second surface 220 (shown in FIG. 14). In other non-limiting example, FIGS. 13 and 14 illustrate that the casing's first 218 and second 220 surfaces are substantially planar and run substantially parallel to each other.

While the casing 212 can be any suitable size, in some non-limiting embodiments, the casing is configured to have a footprint on a circuit board that is substantially similar in size to the footprint of a corresponding IC (e.g., a CPU). Accordingly, unlike some conventional CPU sockets that have a relatively large footprint to accommodate a lever and locking mechanism, some non-limiting embodiments of the described PGA to BGA adaptor 210 are configured to take little to no more real estate on a circuit board than would a CPU that is attached without the adaptor.

The casing 212 can also be of any suitable thickness. In this regard, in some non-limiting embodiments, the distance D1 between the casing's first 218 and second 220 surfaces is as little as a distance selected from about 1 millimeter, about 2 millimeters, about 3 millimeters, and about 4 millimeters. Similarly, in some non-limiting embodiments, the casing has a thickness that is selected from a distance D1 that is as much as about 5 millimeters, about 6 millimeters, about 8 millimeters, and about 10 millimeters. Indeed, in some non-limiting embodiments, the casing is between about 1.2 and about 3 times as thick as a conventional fiberglass circuit board. For instance, in some non-limiting embodiments, the casing has a thickness that is about 2±0.5 times as thick as a conventional fiberglass circuit board.

In addition to the aforementioned characteristics, the casing 212 can be made of any suitable material that allows it to function as intended. In one non-limiting example, the casing comprises a rigid material that is configured to reduce and/or prevent flexing in the adaptor 210 as the adaptor is exposed to mechanical stresses, such as vibration or mechanical shot that occurs as a circuit board comprising the adaptor is used. In another non-limiting example, the casing comprises a material that is capable of electrically insulating the individual pin sockets 216 from each other. In this regard, some examples of suitable materials for the casing include, but are not limited to, a rigid and insulative type of fiberglass, plastic, ceramic, polymer, and/or other similar material.

Turning now to the array 214 of machined pin sockets 216, the PGA to BGA adaptor 210 can comprise any suitable number of pin sockets. Indeed, while in some non-limiting embodiments, the adaptor comprises as few as four pin sockets disposed in an array, in other non-limiting embodiments, the adaptor comprises over 1,000 pin sockets. According to one non-limiting example, however, FIG. 13 shows an embodiment in which the adaptor 210 comprises 940 pin sockets 216.

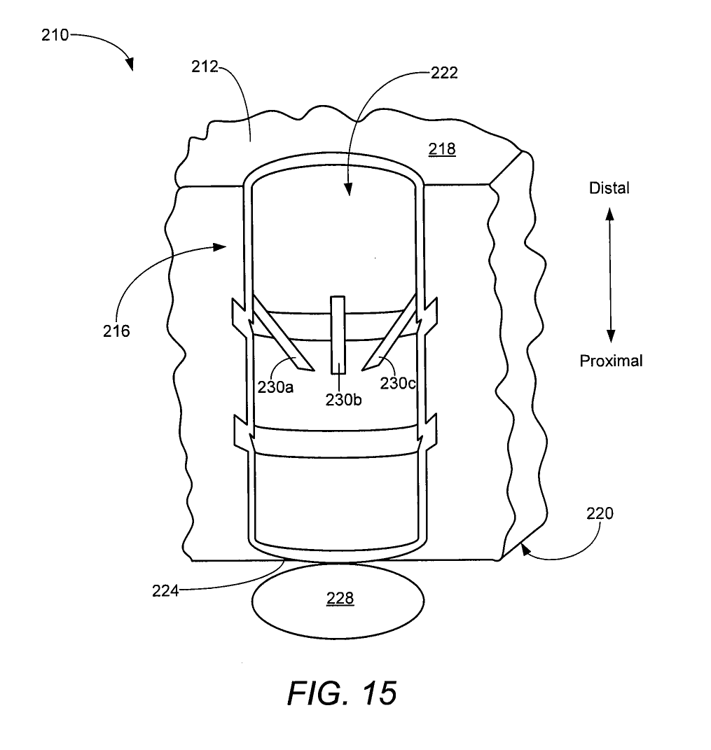

The individual machined pin sockets 216 in the array 214 can have any suitable characteristic. In one non-limiting example, FIGS. 13 and 15 show that, in some embodiments, the pin sockets 216 are hollow and have a barrel-like appearance. While the machined pin sockets in this example can have any suitable shape (including without limitation, a cylindrical, tubular, triangular, rectangular, polygonal, irregular, or other known or novel shape), FIG. 15 shows a non-limiting embodiment in which the machined pin socket 216 has a cylindrical shape.

In another non-limiting example of a suitable characteristic of a machined pin socket 216, FIG. 15 shows that the pin socket 216 defines a pin receptacle opening 222 that is disposed at or adjacent to the casing's first surface 218. Accordingly, the pin socket is configured to receive a pin (not shown) from a PGA of an integrated circuit.

In another non-limiting example, the pin receptacle openings 222 of the machined pin sockets 216 in the array 214 are substantially flush with each other at the casing's first side 218. In this manner, the adaptor 210 is configured to allow an integrated circuit to be uniformly seated on the adaptor.

In still another non-limiting example, FIG. 15 shows the proximal end 224 of the machined pin socket 216 comprises a solder ball 228. While the solder ball in this example can serve any suitable purpose, in some instances, the solder ball is used to electrically and/or physically attach the pin socket (and any IC pin disposed therein) to a circuit board.

In yet another non-limiting example, FIG. 15 shows that in some embodiments the machined pin socket 216 comprises at least one finger contact 230. In this example, the finger contact can serve any suitable function, including, but not limited to, electrically contacting, physically catching, and/or straightening a pin from a PGA of an integrated circuit device.

Where a machined pin socket 216 comprises a contact finger 230, the pin socket can comprise any suitable number of finger contacts. For instance, in some embodiments, the machined pin socket comprises two, three, four, five, six, seven, eight, or more finger contacts. Indeed, in some embodiments, the machined pin socket comprises six contact fingers.

Where the machine pin socket 216 comprises two or more contact fingers, the plurality of fingers can serve any suitable purpose. In one non-limiting example, if one or more finger contacts become damaged or otherwise lose contact with a pin from an integrated circuit pin, one or more other contact fingers are configured to retain electrical contact with the pin. In another non-limiting example, the higher the number of finger contacts that are disposed in the socket, the stronger the physical connection between the socket and a pin disposed therein.

Where a machined pin socket 216 comprises at least one contact finger 230, the contact finger can have any suitable characteristic. In one non-limiting example, the contact finger is resilient. In another non-limiting example, the contact finger can have any suitable shape, including, but not limited to, a bowed, straight, rounded, sharpened, or other known or novel finger contact shape. In still another non-limiting example, the contact finger can be disposed in any suitable location inside the machined pin socket that allows the finger to electrically and physically connect to an integrated circuit pin that is disposed in the pin socket.

In addition to the aforementioned characteristics, each machined pin socket 216 can comprise any other suitable characteristic. By way of non-limiting example, each pin socket can comprise any suitable conductive material, including, but not limited to, copper, gold, brass, platinum, silver, and/or any other material that is capable of allowing the interposer to fulfill its intended purposes.

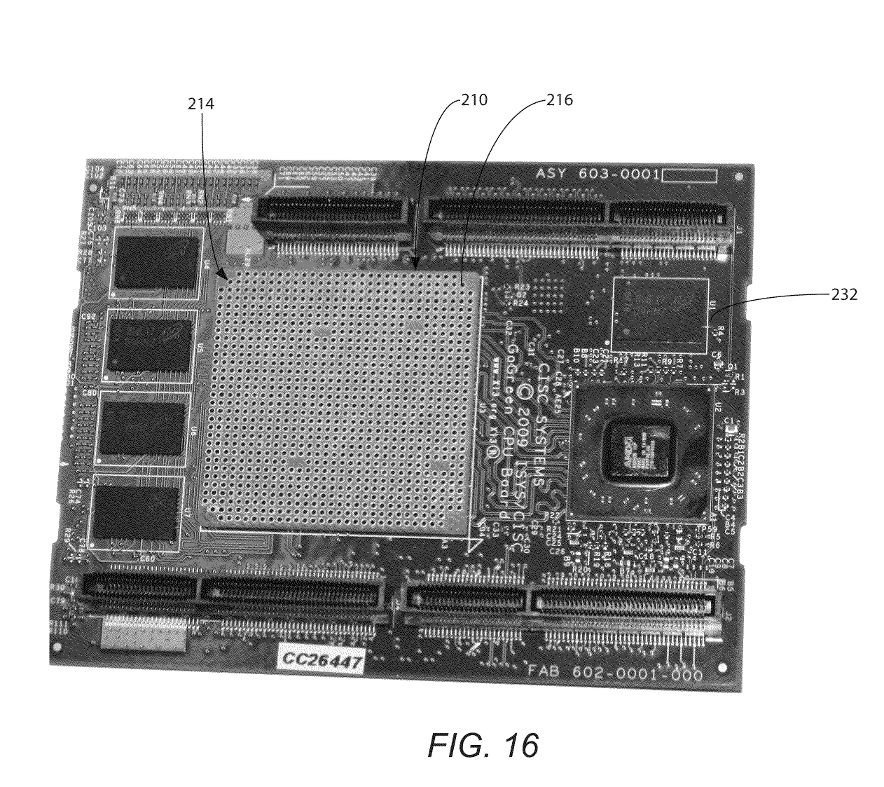

In another non-limiting example, the machined pin sockets 216 can be disposed in the casing 212 in any suitable pattern. By way of illustration, FIG. 16 shows that in at least one embodiment, the array 214 of machined pin sockets 216 is keyed so that a CPU (not shown) can only be attached to the adaptor 210 in a proper orientation.

As described above, the PGA to BGA adaptor 210 comprises a variety of characteristics that makes its use beneficial. In one non-limiting example of such a characteristic, some embodiments of the described adaptor have a footprint that requires little to no more real estate on a circuit board than would a CPU (which is configured to attach to the board via the adaptor) without the adaptor.

In another non-limiting example, because the adaptor 210 is configured to receive an integrated circuit, the adaptor can be soldered or otherwise connected to a circuit board, and the CPU or other integrated circuit can be connected to the adaptor at a later date. As a result, a circuit board comprising the adaptor need not have a CPU installed initially. Accordingly, the PCB and the CPU can be sold separately. Similarly, because the described adaptor is configured to attach to a circuit board without a CPU being attached to the adaptor, a manufacture could buy circuit boards and CPUs and only attach them to each other once a particular order has been made.

In another example, because the adaptor 210 can connect to a circuit board 232 (see FIG. 16) through the use of a BGA, as opposed to using of PGA that penetrates through the board, the adaptor allows electrical circuitry (e.g., circuitry that is not directly electrically connected to the interposer or the IC) to be disposed on the circuit board, on a portion of the circuit board that is disposed directly opposite to the adaptor.

In still another example, because some embodiments of the described adaptor are configured to use pressure between contact fingers and pins from an integrated circuit to attach the circuit to a circuit board (as opposed to soldering the integrated circuit directly to the board), the integrated circuit is selectively removable from circuit board.

Thus, as discussed herein, at least some aspects of the present invention embrace systems and methods for attaching an IC device to a circuit board. In particular, at least some aspects of the present invention relate to systems and methods for attaching an IC, which comprises an array of pins, to a circuit board through the use of an adaptor that comprises a BGA, and which is configured to electrically and physically attach to the circuit board.

### Logic Chip/LED Connection

As mentioned above, at least some aspects of the present invention relate to LED circuitry. Indeed, some embodiments of the present invention take place in association with at least one multi-color LED, such as a bi-color or tri-color LED, being electrically connected such that the LED is capable of emitting each discrete color dictated by the LED's component materials and construction as a visual representation or indication of user desired information or a user defined status. In at least one embodiment, a bi-color LED electrical indicator system includes a bi-color LED. In such embodiments the LED is capable of emitting two colors: a first color in accordance with current flow in one direction and a second color in accordance with current flow in the opposite direction. As with all diodes, the bi-color LED includes two leads or electrical terminals. However, one lead behaves as the cathode while the other lead behaves as the anode relative to the appropriate diode when the current flows in one direction. When the current is reversed though, the former cathode lead behaves as the anode and the former anode lead behaves as the cathode relative to the other diode.

In addition to the bi-color LED, some embodiments of the foregoing system include a first electrical line providing an electrical ground output. In such embodiments the output is ordinarily intended to be connected to and to activate only a single independent unicolor LED. However, the first electrical line is connected to one lead of the bi-color LED and to a pull-up resistor. The pull-up resistor provides current flow in the appropriate direction for activating one of the bi-color LED's two possible colors.

Finally, some embodiments of the foregoing system also include a second electrical line providing an electrical ground output similar to the first output discussed above. In like manner, the second electrical line is connected to the other lead of the bi-color LED and to another pull-up resistor. The pull-up resistor provides current flow in the appropriate direction for activating the other of the bi-color LED's two possible colors. In this manner, the bi-color LED's two discrete colors can both be activated at separate times according to the appropriate electrical output or signal.

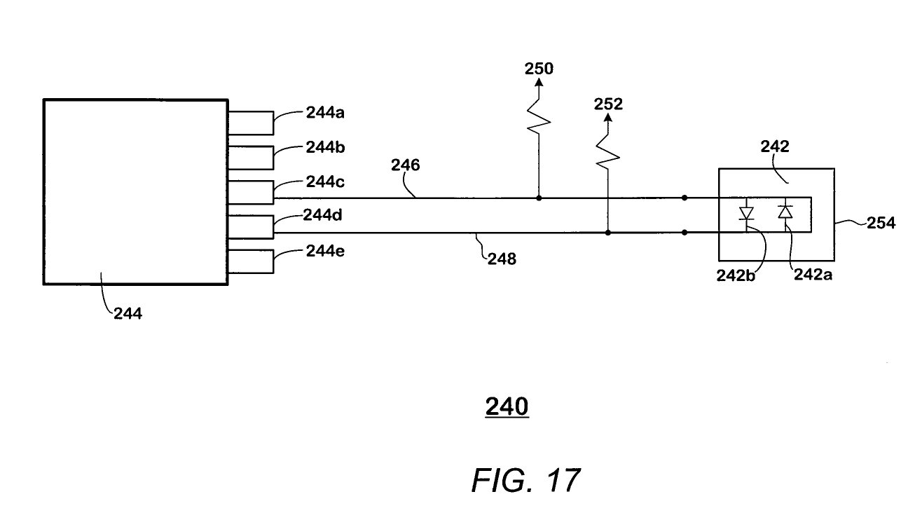

With reference now to FIG. 17, a representative embodiment of multi-color LED electrical indicator system 240 is illustrated. In the illustrated embodiment, system 240 is configured such that a multi-color LED 242 is capable of emitting each discrete color dictated by LED 242's component materials and construction as a visual representation or indication of user desired information or a user defined status. Generally, system 240 is a novel LED circuit. Some embodiments of system 240 include the following component elements: logic device 244, multi-color LED 242 with internal individual semiconductor dies 242a, 242b . . . 242n, logic pins 244a, 244b, 244c, 244d, . . . 244n, electrical lines or wires 246, 248, and resistors 250, 252, each of which will be discussed in greater detail below.

With continued reference to FIG. 17, a representative embodiment of the logic device 244 is provided. Generally, the logic device 244 transmits logic outputs based on known data or information but cannot source current. The underlying known data or information can be provided via programming the logic device 244 before hand, sending the logic device 244 necessary information based on physical system elements or configuration or through software implemented means. In some embodiments, the logic device 244 can be, by way of example, an Ethernet logic chip or other computer logic chips, such as those manufactured by Marvell Semiconductor, Inc. In other embodiments, the logic device 244 may include alternative electrical devices.

The logic device 244 transmits corresponding logic outputs through logic pins 244a, 244b, 244c, 244d, . . . 244n in the form of electrical signals. The logic device 244 can have as few as one logic pin 244a or theoretically the logic device 244 can have an unlimited number of logic pins represented by 244n. Each of the logic pins 244a-n is associated with a unique electrical signal based on unique information known to and transmitted by the logic device 244 as discussed above. In this way, data provided to an end user via the logic device 244 is highly customizable and versatile. By way of non-limiting example, an Ethernet chip 244 may include the following pins: ACT, Link, Duplex, Speed, (i.e., 10 Mb, 100 Mb, 1000 Mb, etc.) and so forth. Each of the aforementioned pins is tasked with transmitting data known to the Ethernet chip 244 at any given time relating to the corresponding title or label of each pin.

The state of logic pins 244a-n is high impedance and thus, as mentioned above, the logic pins 244a-n provide no power on their own. Rather, the logic pins 244a-n go low when the logic device 244 receives and correspondingly transmits particular information. If no data is either known or available, then the corresponding pin simply floats. Said another way, the logic device 244 can only pull the lines associated with each logic pin 244a-n low, otherwise they float up. For example, if a computer system had an Ethernet speed capacity of 100 Mb, but not 1000 Mb, the 1000 Mb pin would simply float while the 100 Mb pin would go low or otherwise ground. If the 100 Mb pin were appropriately connected to a unicolor LED, the unicolor LED would then light up indicating a 100 Mb speed. Since all the pins 244a-n go low in order to transmit appropriate electrical signals, two separate pins cannot merely be connected only to the two LED terminals of a corresponding bi-color LED because neither pin would provide power and thus the bi-color LED would never be activated. Accordingly, according to the present invention the resistors 250 and 252 are needed to facilitate such a connection, as discussed in more detail below.

With continued reference to FIG. 17, a representative embodiment of multi-color LED 242 is provided. While an LED can have as few as one internal semiconductor die 242a, such an LED would necessarily be unicolor. Accordingly, LED 242 is depicted as having a minimum of two internal semiconductor dies 242a and 242b, each of which is manufactured from different semiconductor materials, or doped with different impurities, such that the LED is capable of transmitting a minimum of two discrete colors. However, the LED 242 can include additional internal semiconductor dies represented by “242n.” Alternatively, the LED 242 could be manipulated to give the appearance of multiple colors. For example, a bi-color LED can be toggled between four functional activations: off, one diode activated independently for a given length of time thereby producing one discrete color over that length of time, the other diode activated independently for a given length of time thereby producing the other discrete color over that length of time, or alternating the two colors with sufficient frequency to cause the appearance of a blended third color. For example, a red/green LED operated in this fashion will color blend to produce a yellow appearance. The present invention contemplates the use and manipulation of any multi-color LED having appropriate properties and/or characteristics to produce the desired physical display.

As discussed briefly above, bi-color LEDs are actually two different LEDs housed in one case or lens. They consist of two diodes connected to the same two leads anti-parallel to each other. Current flow in one direction produces one color, and current flow in the opposite direction produces the other color. Tri-color LEDs are two LEDs in one case, but the two LEDs are connected to separate leads so that the two LEDs can be controlled independently and lit simultaneously. A three-lead arrangement is typical with one common lead (anode or cathode). Such LEDs are capable of producing a third color not by merely alternating the two colors with sufficient frequency but rather the two colors are produced simultaneously thereby producing a constant blended third color.

In some embodiments, the LED 242 can be any appropriate LED having any appropriate color or functionality suitable for the intended use. For example, the LED can be a miniature LED, a high power LED, a mid-range LED, or other application specific variations thereon. Likewise, LED 104 can be a standard LED, an organic LED (“OLED”), a quantum dot LED, a diffused lens LED or any other type of LED suitable to its intended use. Likewise, the LED can also be configured in any shape and size suitable for the intended use.

Further, in various embodiments the LED 242 can include any suitable internal semiconductor material, or material doped with suitable impurities, such that desired wavelengths (colors) can be produced. For example, infrared can be created using a gallium arsenide (GaAs) or aluminum gallium arsenide (AlGsAs) semiconductor material, red can be created using an aluminum gallium arsenide (AlGsAs), gallium arsenide phosphide (GaAsP), aluminum gallium indium phosphide (AlGaInP), or gallium (III) phosphide (GaP) semiconductor material, and other discrete colors such as orange, yellow, green, blue, violet, purple, ultraviolet and white can be produced by varying the semiconductor material as known to those of skill in the art. Different wavelengths (colors) also require different voltage parameters to operate as known to those of skill in the art.

In some embodiments, the color of the LED 242 is derived solely from the semiconductor material used in the LED as discussed above. In such embodiments, a lens 254 can be clear or otherwise transparent with no additional color. In other embodiments, the semiconductor die is incorporated or encased in a colored lens 254. The lens 254 can be made from epoxy, resin, plastic, or other suitable polymer based materials. The lens 254 can be colored during the manufacturing process such that the LED 242 can ultimately appear as anyone of a diverse range of colors suitable to the intended application. In this way, standardized colors could be commonly associated with specific information such that by observing the mere color of an LED a user can derive information about the associated electrical device symbolically. In other embodiments, a cap (not shown) can be placed over the top of the lens 254 such that the color of the LED 242 can be visually altered or even prohibited when desirable.

In addition, in some embodiments the LED 242 can be a dedicated flashing LED having an integrated multi-vibrator circuit which causes the LED to flash with a typical period of one second. However, the flash period can be variable to reflect increased or decreased data, to reflect other information or simply to flash at a desired interval. While such flashing LEDs can emit light of a single color, the present invention also contemplates flashing LEDs that can flash between multiple colors and fade through a color sequence using color mixing. Further, such flashing LEDs can be bi-color LEDs as discussed above with the added functionality of one or both LEDs capable of flashing.

While in some embodiments LEDs producing light within the visible spectrum are desired such that a user can observe such light and thereby be informed about the status of a given electronic device, some embodiments contemplate LEDs producing non-visible light, such as infrared. In such embodiments, the LED is observed by an electronic sensor, rather than a user's eye, in order that an appropriate signal may be sent from the LED to the sensor and received by the sensor. In this way, a computer, for example, could independently be programmed to monitor the activity and status of its own individual components or some other electronic device(s). Further, through software implementation, a message could then be produced and sent to a user who desires to know about activity on the computer's component parts or the activity/status of another electronic device.

In some embodiments, the LED 242 is only an indicator lamp. However, in other embodiments, the methods and systems of the present invention could be used to activate the LED 242 for a variety of purposes including lighting, operable printhead operation, text or video display and other illumination based functions where LEDs are suitable. In such embodiments, an unlimited number of LEDs 242 are contemplated.

With continued reference to FIG. 17, a representative embodiment of electrical lines or wires 246 and 248 is provided. The electrical lines/wires 246 and 248 can be composed of any suitable materials such as copper, brass, chrome, nickel, gold, or other conductive anti-corrosive materials. Similarly, the electrical lines/wires 246 and 248 can be composed of any alloy of the foregoing materials or other suitable materials having appropriate properties or characteristics. Further, the electrical lines/wires 246 and 248 can be separate elements, such as standard electrical wires, where the wires are insulated in any manner common to those of skill in the art. Alternatively, the electrical lines/wires 246 and 248 can be formed on or incorporated into a platform common to both logic device 244 and a corresponding device housing the LED 242, such as an Ethernet port having one or more LED indicators, such as a PCB or other electrical board by methods known to those of skill in the art.

With continued reference to FIG. 17, a representative embodiment of the resistors 250 and 252 is provided. In some embodiments, the resistors 250 and 252 are pull-up resistors. In other embodiments, the resistors 250 and 252 can be pull-down resistors (not shown). The basic function of a pull-up resistor is to insure that, given no other input, a circuit assumes a default value by “pulling” the line high. In other words, a pull-up resistor prevents a line from floating. In addition, the key function of a resistor generally is to prevent too much current from flowing through the pull-up circuit.

The pull-up resistors (e.g., resistors 250 and 252) can be composed of any suitable materials such as copper, brass, chrome, nickel, gold, or other conductive anti-corrosive materials. Similarly, the pull-up resistors can be composed of any alloy of the foregoing materials or other suitable materials having appropriate properties or characteristics.

In some embodiments, the pull-up resistors 250 and 252 are connected to the electrical lines (or wires) 246 and 248 such that they “pull-up” the voltage of the non-voltage source wires 246 and 248 toward a voltage source level when all the components on the line are inactive. In this way, when the logic pins 244c and 244d are inactive, no current will flow on the line. In other words, when all other terminating connections on the line are inactive, they are high-impedance and act like they are disconnected. Since the components act as though they are disconnected, the circuit acts as though it is disconnected, and no current will flow on the line, and the voltage of the non-voltage source wire (common between all components on the line) will be that of the voltage source according to Ohm's law. Said yet another way, there is no path to ground when the lines 246 and 248 are both pulled up. However, when one component on the line, such as logic pin 244c, goes active (i.e., transitions from high-impedance to low-impedance based on a signal from the logic device 244), the line grounds and current flows.

In one example, the system 240 operates as follows. For purposes of this non-limiting example, logic pin 244b will be equated with an Ethernet speed of 10 Mb, logic pin 244c will be equated with an Ethernet speed of 100 Mb, and logic pin 244d will be equated with an Ethernet speed of 1000 Mb. Further, for purposes of this example, the logic device 244 will be equated with an Ethernet logic chip and the LED 242 will be equated with a bi-color indicator LED on a corresponding Ethernet port (not shown) all of which is mounted on a PCB (also not shown).

When the PCB upon which the logic chip 244 and the Ethernet port is installed in a corresponding computer system capable of a 100 Mb Ethernet connection, pin 244c goes active based on the systems physical parameters and transitions from high-impedance to low impedance. As a result, line 246 grounds and pull-up resistor 250 permits current to flow in a first direction such that the LED 242a turns on. In some embodiments, the LED 242a may be a color commonly associated with a 100 Mb Ethernet speed, such as green. Colors corresponding to the variable status of the Ethernet connection can be documented for the user so the user knows what each color represents. Simultaneously, logic pin 244d remains high and inactive. Further, pull-up resistor 252 and line 248 remain sufficiently high such that there is no interference on the circuit. In other words, line 248 and LED 242b simply remain inactive. As discussed briefly above, LED 242a can be any desired color, size, shape, or type. Further LED 242a can be a flashing LED.

On the other hand, when the same PCB is installed in a system capable of a 1000 Mb Ethernet connection, pin 244d goes low, pin 244c remains high, line 248 grounds, and pull-up resistor 252 permits current to flow in a second direction opposite the first direction such that LED 242b turns on. In some embodiments, LED 242b may be a color commonly associated with a 1000 Mb Ethernet speed, such as amber. At the same time logic pin 244c remains high and inactive and pull-up resistor 250 and line 246 remain sufficiently high such that there is no interference on the circuit. In other words, line 246 and LED 242a simply remain inactive. As discussed briefly above, LED 242b can be any desired color, size, shape, or type. Further LED 242b can be a flashing LED. In some embodiments, LED 242b can be the same as LED 242a in some respects and different in others. For example, in one embodiment LED 242a may be a flashing LED while LED 242b is not. In another embodiment, the LEDs 242a and 242b may both be flashing LEDs or both may not be. Any variation of the litany of available LEDs is possible.

When the same PCB is installed in a system capable of only a 10 Mb Ethernet connection, pin 244b goes low while pins 244c and 244d remain high. In this way, neither LED 244a nor 244b turns on, rather, the LED 242 remains off. In this manner, three discrete speeds can be represented by a single bi-color LED depending on the system constraints the PCB is connected to. Further, logic pins meant to drive a single unicolor LED can be electrically connected to and activate either of two discrete colors in a single bi-color LED under appropriate circumstances.

While FIG. 17 shows only one logic device 244 and corresponding bi-color LED 242, the present invention contemplates unlimited such systems each having one or more logic devices connected to one or more LEDs. Accordingly, the figure is not meant to be limiting in any sense. For example, logic pins 244a and 244b could be connected to another bi-color LED or a tri-color LED simultaneously. Alternatively, logic pins 244n through 244ₙ₊₁ (where “n” represents an unlimited number) could be connected to additional multi-color LEDs simultaneously. All such connections and systems could operate together or independently from each other. Further, as mentioned above, in other embodiments, the methods and systems of the present invention could be used to activate the LED 242 for a variety of purposes including lighting, operable printhead operation, text or video display and other illumination based functions where LEDs are suitable. In such embodiments, an unlimited number of LEDs 242 are contemplated.

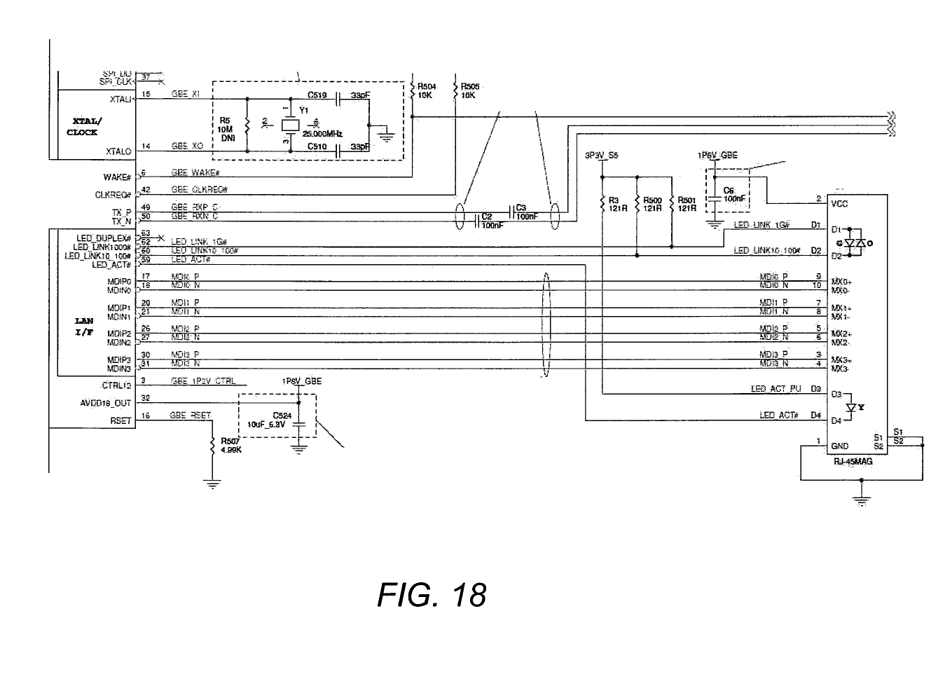

For further reference, FIG. 18 depicts a representative embodiment of a PCB layout for some embodiments of the described LED circuitry.

Thus, as discussed herein, at least some aspects of the present invention embrace multi-color LEDs and LED circuitry. In particular, some aspects of the present invention relate to systems and methods for achieving activation of at least one multi-color LED, such as a bi-color or tri-color LED, using multiple electrical ground outputs or signals intended to activate only a single unicolor LED.

Furthermore, as discussed herein at least some aspects the present invention relate to electronic systems and components. In particular, at least some aspects of the present invention relate to miniaturization techniques, systems, and apparatus relating to power supplies, memory, interconnections, and LEDs.

These illustrations are merely representative of the capabilities the describe systems, methods, apparatus, and techniques for miniaturizing and otherwise improving power supplies, memory, IC connectors, and LED circuitry. Indeed, while illustrative embodiments of the invention have been described herein, the present invention is not limited to the various preferred embodiments described herein, but rather includes any and all embodiments having modifications, omissions, combinations (e.g., of aspects across various embodiments), adaptations and/or alterations as would be appreciated by those in the art based on the present disclosure.

The limitations in the claims are to be interpreted broadly based the language employed in the claims and not limited to examples described in the present specification or during the prosecution of the application, which examples are to be construed as non-exclusive. For example, in the present disclosure, the term “preferably” is non-exclusive and means “preferably, but not limited to.” The term “about” means quantities, dimensions, sizes, formulations, parameters, shapes and other characteristics need not be exact, but may be approximated and/or larger or smaller, as desired, reflecting acceptable tolerances, conversion factors, rounding off, measurement error and the like and other factors known to those of skill in the art. Means-plus-function or step-plus-function limitations will only be employed where for a specific claim limitation all of the following conditions are present in that limitation: a) “means for” is expressly recited; and b) a corresponding function is expressly recited.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

What is claimed is:

1. A miniaturized power supply comprising:
a printed circuit board;
a first active component disposed on a first side of the printed circuit board; and
a second active component disposed on a second side of the printed circuit board, the second side being different from the first side, and wherein the second active component is electrically connected to the first active component.

2. The power supply of claim 1, wherein the first active component and the second active component are disposed directly opposite each other.

3. The power supply of claim 1, wherein the first active component and the second active component are disposed opposite each other so as to only partly overlap each other.

4. The power supply of claim 1, wherein the first active component and the second active component are electrically connected to each other with a via.

5. The power supply of claim 1, wherein a trace length between the first active component and the second active component is substantially equal to a thickness of the printed circuit board.

6. The power supply of claim 1, wherein the first active component and the second active component are electrically connected to each other through a shielded connection.

7. The power supply of claim 6, wherein the shielded connection comprises signal conductor and a plurality of shield structures.

8. The power supply of claim 1, wherein the miniaturized power supply occupies less than about 2.5 square centimeters on each of the first and second sides of the printed circuit board.

9. A system having optimized memory performance, the system comprising:
a circuit board having a top side and a bottom side;
a memory controller coupled to the circuit board;
multiple memory devices soldered directly to the circuit board, each of the memory devices located within about 6.4 centimeters of the memory controller, a first portion of the memory devices being disposed on the top side of the circuit board, a second portion of the memory devices being disposed on the bottom side of the circuit board;
a system clock;
two of more clock lines of substantially equal distances coupling the plurality of memory devices to the system clock; and
a plurality of data lines coupling each of the memory devices directly to the memory controller.

10. The system of claim 9, wherein a portion of each of the memory devices is within about 6.4 centimeters of the memory controller.

11. The system of claim 9, wherein each of the memory devices in their entirety are within about 6.4 centimeters of the memory controller.

12. An interposer, comprising:
a rigid, insulative casing; and
an array of machined pin sockets disposed within the insulative casing, wherein each of a plurality of sockets in the array of machined pin sockets comprises a pin receptacle that opens from a first surface of the insulative casing, and wherein each of the plurality of sockets comprises a solder ball that is disposed at a second surface of the casing.

13. The interposer of claim 12, wherein each of the plurality of sockets comprise at least 2 internal finger contacts.

14. The interposer of claim 12, wherein each of the plurality of sockets comprise 3 to 10 finger contacts.

15. The interposer of claim 13, wherein the internal finger contacts are resilient.

16. The interposer of claim 12, wherein the insulative casing comprises a fiberglass substrate having a thickness between about 1 millimeter and about 8 millimeters.

17. The interposer of claim 12, wherein the array of machined pin sockets is keyed to receive an integrated circuit in a proper orientation.

18. The interposer of claim 12, wherein a footprint of the interposer is substantially equal in size to a footprint of an integrated circuit that connects to the interposer.

19. The interposer of claim 12, wherein the interposer is electrically coupled to a first side of a printed circuit board, and wherein electrical circuitry that is not directly electrically connected to the interposer is disposed directly opposite to the interposer on the second side of the printed circuit board.

20. A bi-color LED electrical indicator system comprising:
a bi-color LED capable of emitting a first color in accordance with a first current flow direction and a second color in accordance with a second current flow direction opposite the first current flow direction, the bi-color LED also having a first lead and a second lead;
a first electrical line providing a first electrical ground output intended to be connected to and to activate only a single independent unicolor LED, the first electrical line being connected to the first lead of the bi-color LED and to a first pull-up resistor, the first pull-up resistor providing current flow in the first current flow direction in order to activate the first color; and
a second electrical line providing a second electrical ground output intended to be connected to and to activate only a single independent unicolor LED, the second electrical line being connected to the second lead of the bi-color LED and to a second pull-up resistor, the second pull-up resistor providing current flow in the second current flow direction in order to activate the second color.
